(19) United States
(12) Patent Application Publication
(10) Pub. No.: US 2025/0147074 A1
(43) Pub. Date: May 8, 2025

(54) CURRENT MEASUREMENT MODULE

(71) Applicant: Asahi Kasei Microdevices Corporation, Tokyo (JP)

(72) Inventor: Takehiro MARUYAMA, Tokyo (JP)

(21) Appl. No.: 18/934,255

(22) Filed: Nov. 1, 2024

(30) Foreign Application Priority Data
Nov. 2, 2023 (JP) 2023-188286
Oct. 30, 2024 (JP) 2024-190770

(51) Int. Cl. G01R 15/20; G01R 19/00

(52) U.S. Cl. CPC G01R 15/202; G01R 19/0092

(57) ABSTRACT

There is provided a current measurement module. The current measurement module includes: a conductor including two main body portions arranged side by side in a first direction, and two current path portions arranged side by side in a second direction orthogonal to the first direction with a through hole interposed therebetween and for connecting the two main body portions; and a magnetic field sensing element including a magnetosensitive surface for detecting magnetic fields generated by currents flowing through the two current path portions, wherein the through hole has a protruding portion which locally protrudes in the second direction only on one side adjacent to a current path portion, and, in the current path portion on the one side, a narrow portion having a narrower width in the second direction than that of another current path portion on another side is formed.

The contents of the following patent application(s) are incorporated herein by reference:

NO. 2023-188286 filed in JP on Nov. 2, 2023

NO. 2024-190770 filed in JP on Oct. 30, 2024.

### BACKGROUND

### 1. Technical Field

The present invention relates to a current measurement module.

### 2. Related Art

Patent document 1 discloses “a current sensor comprising a current path provided with a long hole along a direction of flow of a to-be-measured current”. Patent document 2 discloses “a sensor and procedure for measuring busbar current with skin effect correction”.

### PRIOR ART DOCUMENTS

### Patent Document

Patent Document 1: Japanese Patent Application Publication No. 2014-055790

Patent Document 2: International Publication No. 2008/030129

### BRIEF DESCRIPTION OF THE DRAWINGS

FIG. 1 is a perspective view illustrating an example of a schematic configuration of a current measurement module 100 according to the present embodiment.

FIG. 2 is a top view illustrating the example of the schematic configuration of the current measurement module 100 according to the present embodiment.

FIG. 3 is a side sectional view illustrating the example of the schematic configuration of the current measurement module 100 according to the present embodiment.

FIG. 4 is a top view illustrating a schematic configuration of a current measurement module 101 of Case 1.

FIG. 5 is a graph illustrating how a positional shift of a magnetic field sensing unit 20 in an x direction influences frequency characteristics for the current measurement module 101 of Case 1.

FIG. 6 is a top view illustrating a schematic configuration of a current measurement module 102 of Case 2.

FIG. 7 is a graph illustrating how the positional shift of the magnetic field sensing unit 20 in the x direction influences frequency characteristics for the current measurement module 102 of Case 2.

FIG. 8 is a top view illustrating a schematic configuration of a current measurement module 103 of Case 3.

FIG. 9 is a graph illustrating how the positional shift of the magnetic field sensing unit 20 in the x direction influences frequency characteristics for the current measurement module 103 of Case 3.

FIG. 10 is a top view illustrating a schematic configuration of a current measurement module 104 of Case 4.

FIG. 11 is a graph illustrating how the positional shift of the magnetic field sensing unit 20 in the x direction influences frequency characteristics for the current measurement module 104 of Case 4.

FIG. 12 illustrates how a length of (c)=(g) of the current measurement module 100 influences frequency characteristics.

FIG. 13 is a top view illustrating a schematic configuration of a current measurement module 105 of Case 5.

FIG. 14 is a graph illustrating how the positional shift of the magnetic field sensing unit 20 in the x direction influences frequency characteristics for the current measurement module 105 of Case 5.

FIG. 15 is a top view illustrating a schematic configuration of a current measurement module 106 of Case 6.

FIG. 16 is a graph illustrating how the positional shift of the magnetic field sensing unit 20 in the x direction influences frequency characteristics for the current measurement module 106 of Case 6.

FIG. 17 is a top view illustrating a schematic configuration of a current measurement module 107 of Case 7.

FIG. 18 is a graph illustrating how the positional shift of the magnetic field sensing unit 20 in the x direction influences frequency characteristics for the current measurement module 107 of Case 7.

FIG. 19 illustrates how a length of (j) of the current measurement module 106 or 107 (see FIG. 15 or FIG. 17) influences frequency characteristics.

FIG. 20 is a top view illustrating a schematic configuration of a current measurement module 108 of Case 8.

FIG. 21 is a graph illustrating how the positional shift of the magnetic field sensing unit 20 in the x direction influences frequency characteristics for the current measurement module 108 of Case 8.

FIG. 22 is a top view illustrating a schematic configuration of a current measurement module 109 of Case 9.

FIG. 23 is a graph illustrating how the positional shift of the magnetic field sensing unit 20 in the x direction influences frequency characteristics for the current measurement module 109 of Case 9.

FIG. 24 is a top view illustrating a schematic configuration of a current measurement module 110 of Case 10.

FIG. 25 is a graph illustrating how the positional shift of the magnetic field sensing unit 20 in the x direction influences frequency characteristics for the current measurement module 110 of Case 10.

FIG. 26 illustrates how a length of (e) of the current measurement module 100 influences frequency characteristics.

FIG. 27 is a top view illustrating a schematic configuration of a current measurement module 111 of Case 11.

FIG. 28 is a graph illustrating how the positional shift of the magnetic field sensing unit 20 in the x direction influences frequency characteristics for the current measurement module 111 of Case 11.

FIG. 29 is a top view illustrating a schematic configuration of a current measurement module 112 of Case 12.

FIG. 30 is a graph illustrating how the positional shift of the magnetic field sensing unit 20 in the x direction influences frequency characteristics for the current measurement module 112 of Case 12.

FIG. 31 is a top view illustrating a schematic configuration of current measurement modules 113 to 115 of Cases 13 to 15.

FIG. 32 illustrates how a length of (h) of the current measurement modules 113 to 115 of Cases 13 to 15 influences frequency characteristics.

FIG. 33 is a top view illustrating a schematic configuration of current measurement modules 116 to 120 of Cases 16 to 20.

FIG. 34 illustrates how a length of (g) of the current measurement modules 116 to 120 of Cases 16 to 20 influences frequency characteristics.

FIG. 35 is a perspective view illustrating an example of a schematic configuration of a current measurement module 200 according to a second embodiment.

FIG. 36 is a side sectional view illustrating the example of the schematic configuration of the current measurement module 200 according to the second embodiment.

FIG. 37 is a perspective view illustrating another example of the schematic configuration of the current measurement module 200 according to the second embodiment.

FIG. 38 is a side sectional view illustrating the another example of the schematic configuration of the current measurement module 200 according to the second embodiment.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solution of the invention.

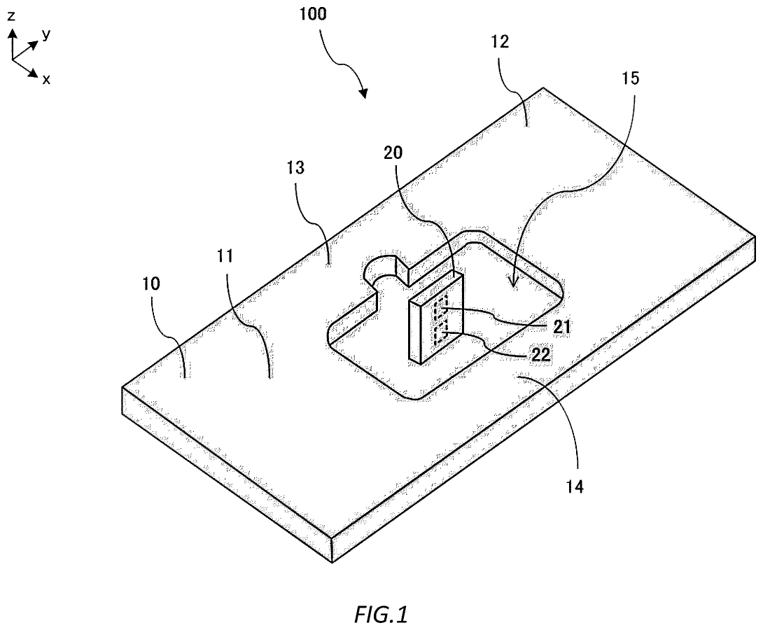

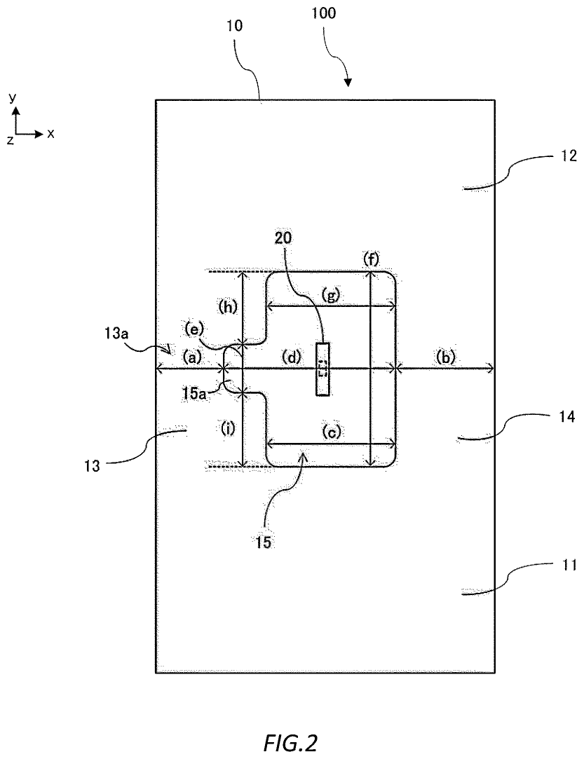

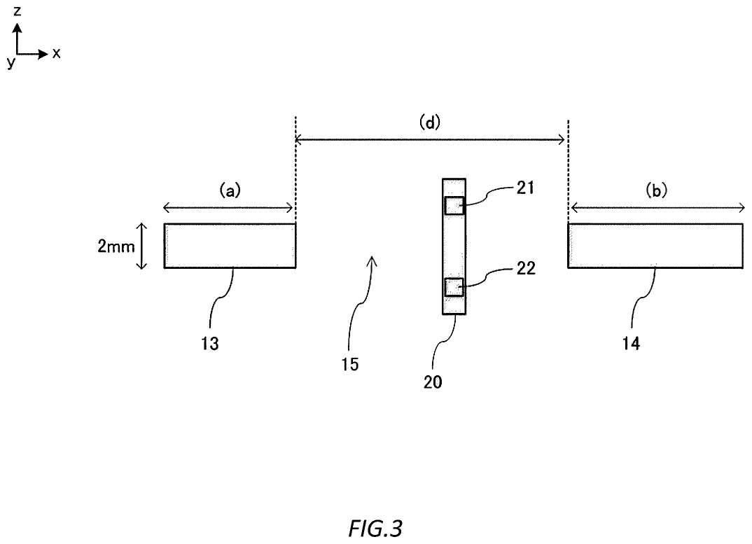

FIG. 1 is a perspective view illustrating an example of a schematic configuration of a current measurement module 100 according to the present embodiment. FIG. 2 is a top view illustrating the example of the schematic configuration of the current measurement module 100 according to the present embodiment. FIG. 3 is a side sectional view illustrating the example of the schematic configuration of the current measurement module 100 according to the present embodiment. In each figure, an xyz coordinate system is illustrated. A first direction in the claims refers to a y direction, a second direction refers to an x direction, and a third direction refers to a z direction. As illustrated in FIG. 1 to FIG. 3, the current measurement module 100 includes a conductor 10 and a magnetic field sensing unit 20. The conductor 10 includes two main body portions 11 and 12 arranged side by side in the first direction, and two current path portions 13 and 14 arranged side by side in the x direction orthogonal to the y direction with a through hole 15 interposed therebetween and for connecting the two main body portions. Note that, the conductor 10 is also referred to as a “busbar”. The magnetic field sensing unit 20 includes magnetic field sensing elements 21 and 22 each including a magnetosensitive surface for detecting magnetic fields generated by currents flowing through the two current path portions 13 and 14.

As illustrated in FIG. 1 to FIG. 3, the two main body portions 11 and 12 are arranged side by side in the y direction. The two current path portions 13 and 14 are disposed between the two main body portions 11 and 12 and extend in parallel with each other, and are for connecting the two main body portions 11 and 12. The through hole 15 is provided between the two current path portions 13 and 14. To-be-measured current flows through each of the two current path portions 13 and 14 in a same direction. In the present embodiment, the two current path portions 13 and 14 each are a conductor that has a rectangular shape in a transverse cross-section and extends along a straight line. Note that, the two current path portions 13 and 14 may have any shape, such as a circular or elliptical shape, in the transverse cross-section.

As illustrated in FIG. 2, the through hole 15 has a protruding region 15a which locally

protrudes in the x direction only on one side adjacent to a current path portion of the two current path portions 13 and 14, that is, the current path portion 13 in FIG. 2, and, in the current path portion 13 on the one side, a narrow region 13a having a narrower width in the x direction than that of the current path portion 14 on another side is formed. In FIG. 2, a length of the narrow region 13a in the x direction is (a); a length of the current path portion 14 in the x direction is (b); a length of a portion of the through hole 15 lower than the protruding region 15a in the x direction is (c); a length of a portion of the through hole 15 where the protruding region 15a is formed in the x direction is (d); a length of the protruding region 15a in the y direction is (e); a length of the through hole 15 in the y direction is (f); a length of a portion of the through hole 15 higher than the protruding region 15a in the x direction is (g); a length of the portion of the through hole 15 higher than the protruding region 15a in the y direction is (h); and a length of the portion of the through hole 15 lower than the protruding region 15a in the y direction is (i). Additionally, the current path portion 14 of the two current path portions 13 and 14 has a uniform width (b) in the y direction. Here, the uniform width (b) is intended to mean uniformity at the point of design, and changes in the width due to manufacturing variations or the like are encompassed within the uniformity according to the present embodiment.

As illustrated in FIGS. 1 to 3, the magnetic field sensing unit 20 includes the two magnetic field sensing elements 21 and 22. The two magnetic field sensing elements 21 and 22 are arranged side by side in the z direction. When viewed from the z direction, the two magnetic field sensing elements 21 and 22 are arranged at a position where they face the protruding region 15a within the through hole 15. In other words, when viewed from the x direction, the two magnetic field sensing elements 21 and 22 are arranged in a range where the protruding region 15a of the through hole 15 is formed. Note that, even when the magnetic field sensing elements are at a position where they do not overlap the conductor 10 in the z direction, that is, even when they are located higher or lower than the conductor 10 in the z direction, it may be considered that the two magnetic field sensing elements 21 and 22 and the protruding region 15a face each other provided that the protruding region 15a and the magnetic field sensing elements 21 and 22 are at a same position in the y direction, and when viewed from the x direction, it may be considered that the two magnetic field sensing elements 21 and 22 are arranged in the range where the protruding region 15a of the through hole 15 is formed. Note that, an embodiment may be contemplated in which the magnetic field sensing unit 20 includes only one magnetic field sensing element.

FIG. 3 is a side sectional view of the current measurement module 100 taken along the protruding region 15a portion of the through hole 15. As illustrated in FIG. 3, the two magnetic field sensing elements 21 and 22 are arranged at higher and lower than the conductor 10 in the z direction, respectively. In addition, the two magnetic field sensing elements 21 and 22 of the magnetic field sensing unit 20 may be arranged such that a boundary plane where a magnetic field in the x direction generated by a current flowing through the conductor 10 is zero is interposed therebetween in the z direction. A thickness of the conductor 10 in the z direction is, e.g., 2 mm.

The two magnetic field sensing elements 21 and 22 detect intensities of the magnetic fields each generated on each magnetosensitive surface by the to-be-measured currents flowing through the two current path portions 13 and 14 in the y direction, respectively, and output a detection signal depending on a difference between the intensities each detected by each of the two magnetic field sensing elements 21 and 22. That is, in the present embodiment, the detection signal output by a combination of the two magnetic field sensing elements 21 and 22 is a differential output. The two magnetic field sensing elements 21 and 22 are arranged side by side in the z direction orthogonal to the y direction and the x direction, and each of the two magnetic field sensing elements 21 and 22 includes a magnetosensitive surface for detecting a component in the x direction of the magnetic fields generated by currents flowing through the two current path portions 13 and 14.

As each of the two magnetic field sensing elements 21 and 22, a magnetoelectric conversion element can be used, and as the magnetoelectric conversion element, for example, a Hall element, which can obtain a detection signal proportional to a magnitude of a magnetic flux density, can be used. Note that, as the magnetoelectric conversion element, a magneto-resistive element, a magnetic impedance element or the like may be used besides the Hall element. Furthermore, any unit that can output a unique detection signal for an applied magnetic flux density, such as a magnetic sensor IC obtained by combining these magnetoelectric conversion elements and an IC processing circuit, can be used as each of the two magnetic field sensing elements 21 and 22. The two magnetic field sensing elements 21 and 22 may each have a different shape or size.

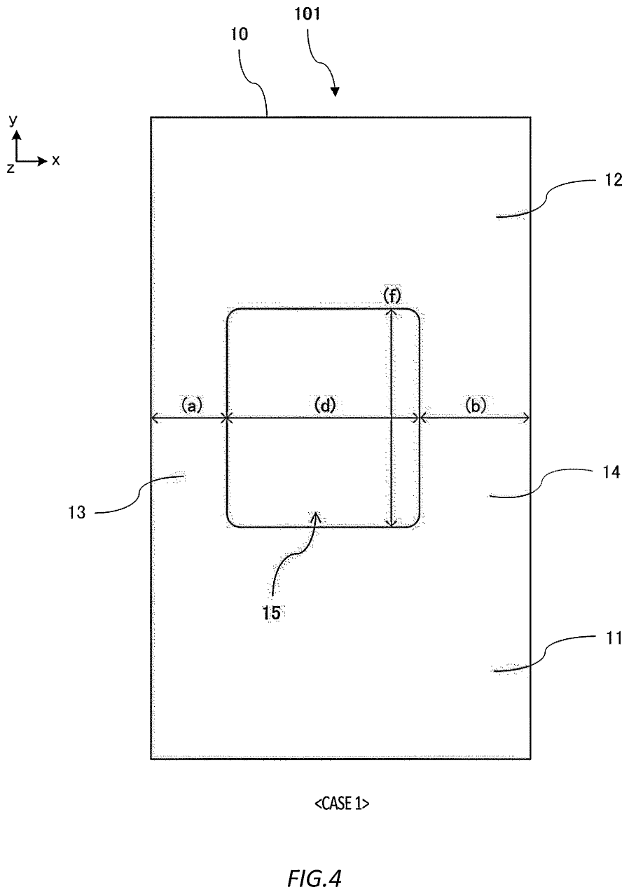

FIG. 4 is a top view illustrating a schematic configuration of a current measurement module 101 of Case 1. In FIG. 4, although the magnetic field sensing unit 20 is arranged within the through hole 15, the illustration thereof is omitted. In the current measurement module 101 of Case 1, the through hole 15 has a rectangular shape and does not include the protruding region 15a which locally protrudes in the through hole 15 as illustrated in FIG. 2. Accordingly, the current path portion 13 is not formed with the narrow region 13a and has a rectangular shape. Other components are the same as those in the current measurement module 100 in FIG. 2, so the description thereof is omitted. In FIG. 4, (a)=3.5 mm, (b)=5.5 mm, (d)=9 mm, and (f)=12.5 mm.

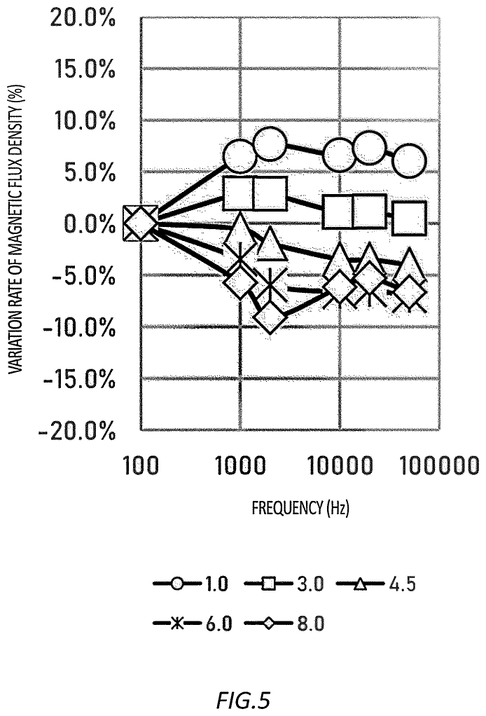

FIG. 5 is a graph illustrating how a positional shift of the magnetic field sensing unit 20 in the x direction influences frequency characteristics for the current measurement module 101 of Case 1. FIG. 5 indicates a variation rate of a magnetic flux density with respect to 100 Hz (%), the magnetic flux density being detected when the two magnetic field sensing elements 21 and 22 of the magnetic field sensing unit 20 move in the x direction within the through hole 15. In FIG. 5, open white circles indicate cases where a distance in the x direction between the right end of the current path portion 13 on the left side and a center position between the two magnetic field sensing elements 21 and 22 is 1 mm; squares indicate cases where the distance is 3 mm; triangles indicate cases where the distance is 4.5 mm; asterisks indicate cases where the distance is 6 mm; and diamonds indicate cases where the distance is 8 mm.

In FIG. 5, the horizontal axis represents a frequency of a current flowing through the current measurement module 100. In FIG. 5, the vertical axis represents the variation rate of the magnetic flux density with respect to 100 Hz (%), the magnetic flux density being detected by the two magnetic field sensing elements 21 and 22. If a difference between a maximum value and a minimum value of the variation rate of the magnetic flux density to be detected (%) is small even when the two magnetic field sensing elements 21 and 22 move in the x direction within the through hole 15, a resulting tolerance for the positional shift of the two magnetic field sensing elements 21 and 22 in the x direction will be high, which is preferable. In contrast, if the difference between the maximum value and the minimum value of the variation rate of the magnetic flux density to be detected is large when the two magnetic field sensing elements 21 and 22 move in the x direction within the through hole 15, the resulting tolerance for the positional shift of the two magnetic field sensing elements 21 and 22 in the x direction will be low, which is not preferable. Note that, in the description below, the difference between the maximum value and the minimum value of the variation rate of the magnetic flux density to be detected may be referred to as the difference in the variation rate of the magnetic flux density, or simply, the difference in the variation rate.

As illustrated in FIG. 5, in the current measurement module 101 of Case 1, when the two magnetic field sensing elements 21 and 22 are close to the current path portion 13 (indicated by the open white circles), the variation rate mostly exceeds +5%. In addition, when the two magnetic field sensing elements 21 and 22 are close to the current path portion 14 (indicated by the diamonds), the variation rate is mostly in a range from −5% to −10%. Accordingly, when the two magnetic field sensing elements 21 and 22 move in the x direction, there is a difference of approximately 10 to 15% in the variation rate. Accordingly, it is shown that the current measurement module 101 of Case 1 has a low tolerance for the positional shift of the magnetic field sensing unit 20 in the x direction.

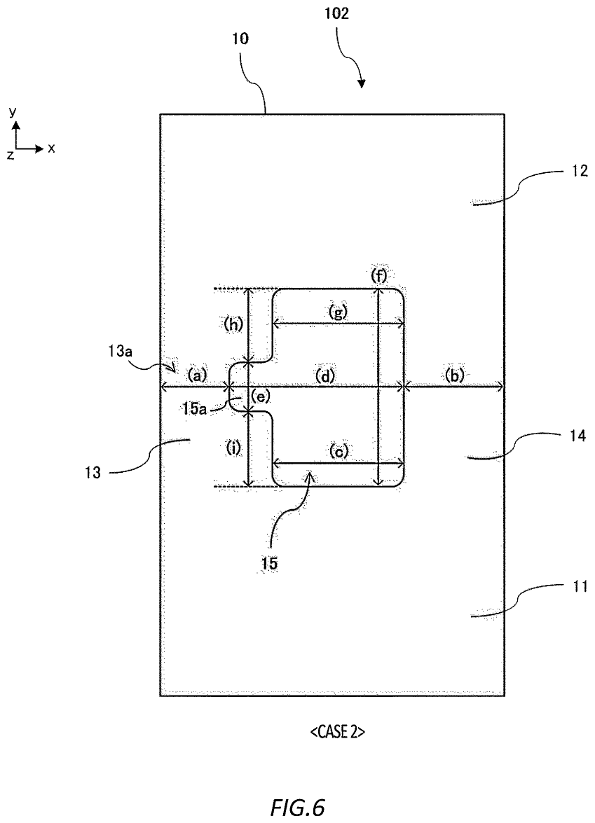

FIG. 6 is a top view illustrating a schematic configuration of a current measurement module 102 of Case 2. In FIG. 6, although the magnetic field sensing unit 20 is arranged within the through hole 15, the illustration thereof is omitted. In the current measurement module 102 of Case 2, as in the current measurement module 100 illustrated in FIG. 2, the through hole 15 has the protruding region 15a which locally protrudes in the x direction only on one side adjacent to the current path portion 13, and, in the current path portion 13 on the one side, the narrow region 13a is formed. In FIG. 6, (a)=3.5 mm, (b)=5.5 mm, (c)=7 mm, (d)=9 mm, (e)=2.6 mm, (f)=12.5 mm, (g)=7 mm, (h)=4.95 mm, and (i)=4.95 mm.

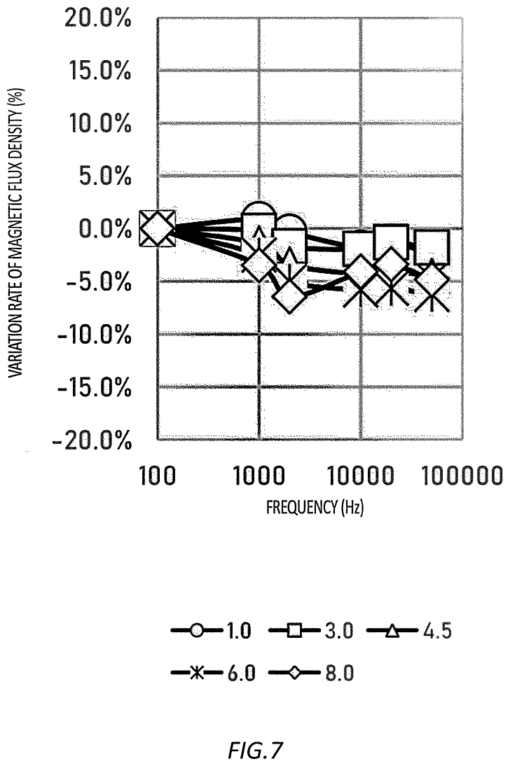

FIG. 7 is a graph illustrating how the positional shift of the magnetic field sensing unit 20 in the x direction influences frequency characteristics for the current measurement module 102 of Case 2. FIG. 7 indicates a variation rate of a magnetic flux density with respect to 100 Hz (%), the magnetic flux density being detected when the two magnetic field sensing elements 21 and 22 of the magnetic field sensing unit 20 move in the x direction within the through hole 15. In FIG. 7, open white circles indicate cases where a distance in the x direction between the right end of the narrow region 13a of the current path portion 13 on the left side and a center position between the two magnetic field sensing elements 21 and 22 is 1 mm; squares indicate cases where the distance is 3 mm; triangles indicate cases where the distance is 4.5 mm; asterisks indicate cases where the distance is 6 mm; and diamonds indicate cases where the distance is 8 mm.

As illustrated in FIG. 7, in the current measurement module 102 of Case 2, when the two magnetic field sensing elements 21 and 22 are close to the current path portion 13 (indicated by the open white circles), the variation rate is mostly within a range from 0% to −3%. In addition, when the two magnetic field sensing elements 21 and 22 are close to the current path portion 14 (indicated by the diamonds), the variation rate is mostly in a range from −5% to −8%. Accordingly, when the two magnetic field sensing elements 21 and 22 move in the x direction, the variation rate converges into a difference of roughly 5%. Accordingly, it is shown that the current measurement module 102 of Case 2 has a high tolerance for the positional shift of the magnetic field sensing unit 20 in the x direction.

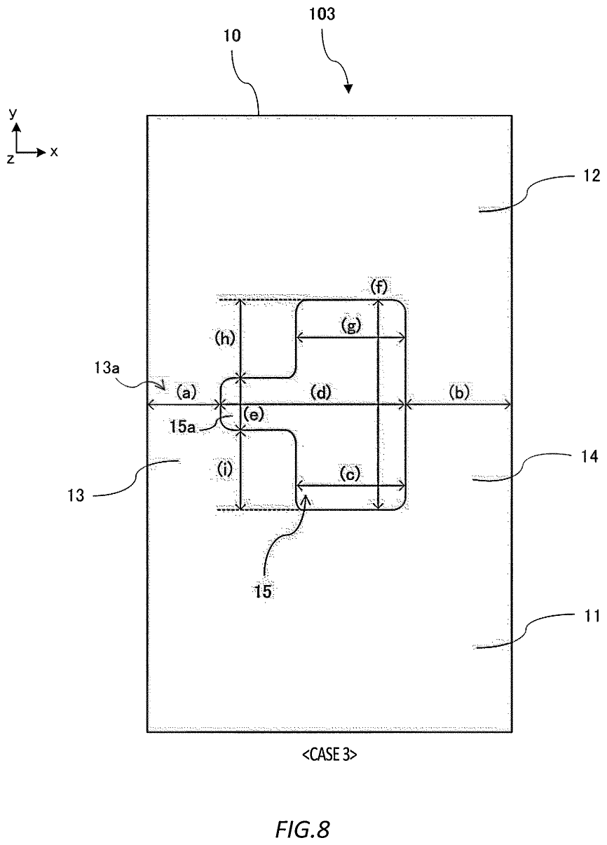

FIG. 8 is a top view illustrating a schematic configuration of a current measurement module 103 of Case 3. In FIG. 8, although the magnetic field sensing unit 20 is arranged within the through hole 15, the illustration thereof is omitted. In the current measurement module 103 of Case 3, a length of the protruding region 15a in the x direction is longer than that in the current measurement module 100 illustrated in FIG. 2, and instead, a length of any remaining portion of the through hole 15 other than the protruding region 15a in the x direction is correspondingly shorter. In FIG. 8, (a)=3.5 mm, (b)=5.5 mm, (c)=5 mm, (d)=9 mm, (e)=2.6 mm, (f)=12.5 mm, (g)=5 mm, (h)=4.95 mm, and (i)=4.95 mm.

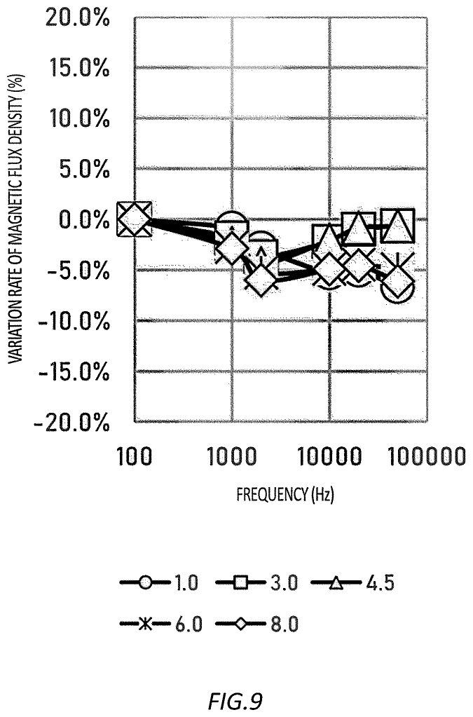

FIG. 9 is a graph illustrating how the positional shift of the magnetic field sensing unit 20 in the x direction influences frequency characteristics for the current measurement module 103 of Case 3. FIG. 9 indicates a variation rate of a magnetic flux density with respect to 100 Hz (%), the magnetic flux density being detected when the two magnetic field sensing elements 21 and 22 of the magnetic field sensing unit 20 move in the x direction within the through hole 15. Other elements in FIG. 9 are the same as those in FIG. 7, so the description thereof is omitted.

As illustrated in FIG. 9, in the current measurement module 103 of Case 3, when the two magnetic field sensing elements 21 and 22 are at a distance of 3 mm from the current path portion 13 (indicated by the squares), the variation rate is mostly within a range from 0% to −5%. In addition, when the two magnetic field sensing elements 21 and 22 are close to the current path portion 14 (indicated by the diamonds), the variation rate is mostly in a range from −3% to −8%. Accordingly, when the two magnetic field sensing elements 21 and 22 move in the x direction, the variation rate converges into a difference of roughly 8%. Accordingly, it is shown that the current measurement module 103 of Case 3 has a high tolerance for the positional shift of the magnetic field sensing unit 20 in the x direction.

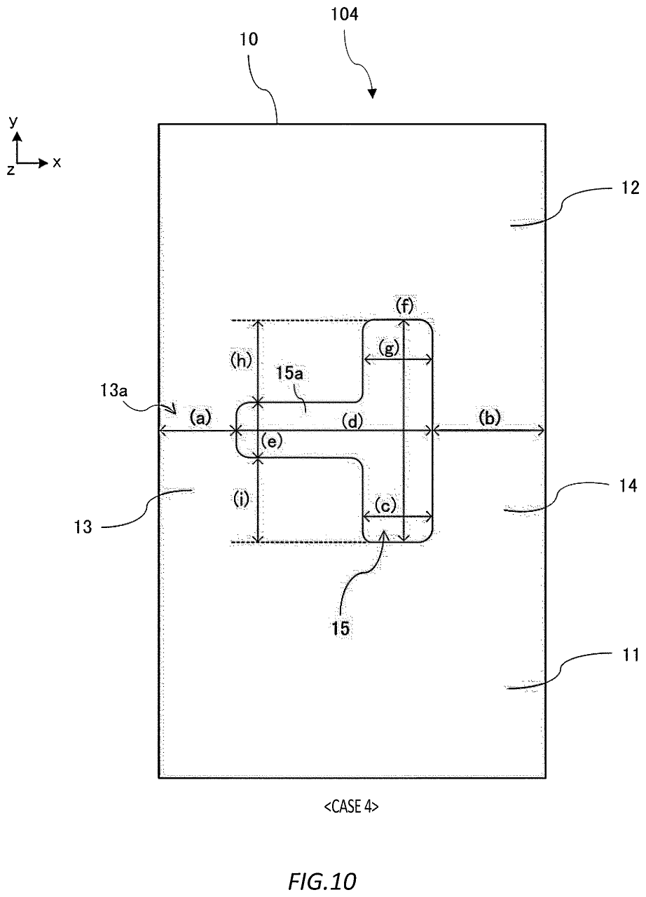

FIG. 10 is a top view illustrating a schematic configuration of a current measurement module 104 of Case 4. In FIG. 10, although the magnetic field sensing unit 20 is arranged within the through hole 15, the illustration thereof is omitted. In the current measurement module 104 of Case 4, the length of the protruding region 15a in the x direction is further longer than that in the current measurement module 103 of Case 3 illustrated in FIG. 8, and instead, the length of any remaining portion of the through hole 15 other than the protruding region 15a in the x direction is correspondingly further shorter. In FIG. 10, (a)=3.5 mm, (b)=5.5 mm, (c)=3 mm, (d)=9 mm, (e) =2.6 mm, (f)=12.5 mm, (g)=3 mm, (h)=4.95 mm, and (i)=4.95 mm.

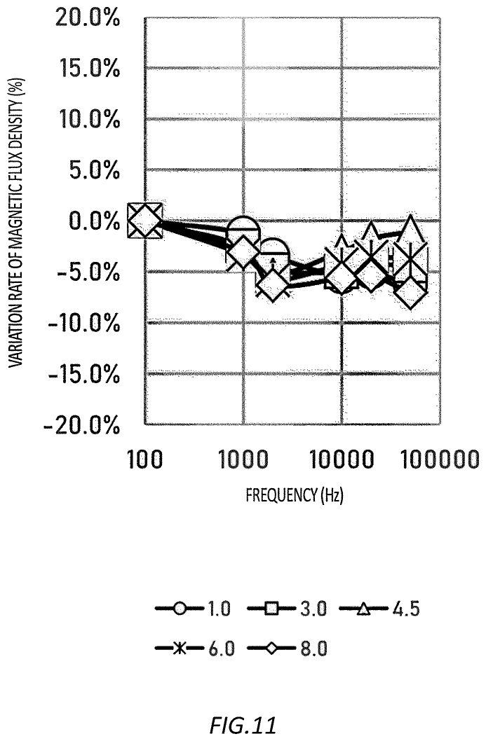

FIG. 11 is a graph illustrating how the positional shift of the magnetic field sensing unit 20 in the x direction influences frequency characteristics for the current measurement module 104 of Case 4. FIG. 11 indicates a variation rate of a magnetic flux density with respect to 100 Hz (%), the magnetic flux density being detected when the two magnetic field sensing elements 21 and 22 of the magnetic field sensing unit 20 move in the x direction within the through hole 15. Other elements in FIG. 11 are the same as those in FIG. 7, so the description thereof is omitted.

As illustrated in FIG. 11, in the current measurement module 104 of Case 4, when the two magnetic field sensing elements 21 and 22 are close to the current path portion 13 (indicated by the open white circles), the variation rate is mostly within a range from 0% to −5%. In addition, when the two magnetic field sensing elements 21 and 22 are close to the current path portion 14 (indicated by the diamonds), the variation rate is mostly in a range from −5% to −8%. Accordingly, when the two magnetic field sensing elements 21 and 22 move in the x direction, the variation rate converges into a difference of roughly 5%. Accordingly, it is shown that the current measurement module 104 of Case 4 has a high tolerance for the positional shift of the magnetic field sensing unit 20 in the x direction.

From the above, it is shown that in comparison of the current measurement modules 101 to 104 of Case 1 to Case 4 with each other, only the current measurement module 101 of Case 1 has the low tolerance for the positional shift of the magnetic field sensing unit 20 in the x direction and the current measurement modules 102 to 104 of Case 2 to Case 4 each have the high tolerance for the positional shift of the magnetic field sensing unit 20 in the x direction. In the current measurement module 101 of Case 1, the through hole 15 has a rectangular shape, whereas, in the current measurement modules 102 to 104 of Case 2 to Case 4, the through hole 15 has the protruding region 15a which locally protrudes on one side adjacent to the current path portion 13. Accordingly, it is shown that a structure in which the through hole 15 has the protruding region 15a can improve the tolerance for the positional shift of the magnetic field sensing unit 20 in the x direction.

This is considered to be attributed to the fact that the through hole 15 has the protruding region 15a which locally protrudes on one side adjacent to the current path portion 13 and the narrow region 13a is formed on the one side adjacent to the current path portion 13, which causes a concentration of currents inside the narrow region 13a and a decrease in change of current density in the current path portion 13 depending on frequency due to skin effect. This is also considered to be attributed to the fact that the width of any remaining portion of the current path portion 13 other than the narrow region 13a gets larger and electrical resistance in the current path portion 13 gets smaller, which causes a decrease in current flowing through the current path portion 14 and a decrease in change of current density in the current path portion 14 depending on frequency due to skin effect.

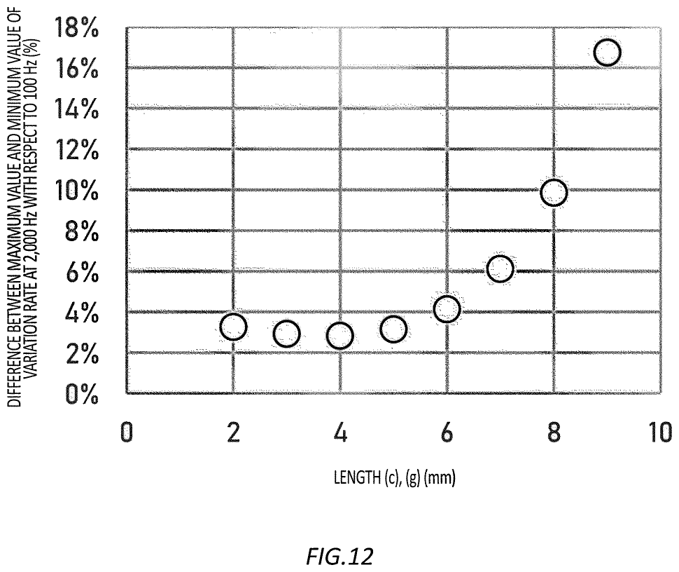

FIG. 12 illustrates how a length of (c)=(g) of the current measurement module 100 influences frequency characteristics. The horizontal axis in FIG. 12 represents the length of (c)=(g) of the current measurement module 100 (mm), and the vertical axis in FIG. 12 represents a difference between a maximum value and a minimum value of the variation rate of the magnetic flux density at 2,000 Hz with respect to 100 Hz (%), the magnetic flux density being detected by the two magnetic field sensing elements 21 and 22 of the magnetic field sensing unit 20 when the two magnetic field sensing elements 21 and 22 move by a total of 7 mm in the x direction within the through hole 15.

As illustrated in FIG. 12, a shorter length of (c)=(g) of the current measurement module 100 leads to a smaller difference in the variation rate of the magnetic flux density, which can be said to have a preferable influence on the frequency characteristics. Meanwhile, since the difference in the variation rate of the magnetic flux density converges when the length of (c)=(g) is equal to or less than 6 mm, it is shown that the length equal to or less than 6 mm for (c)=(g) would suffice. Accordingly, the widths (c) and (g) of the remaining portions of the through hole 15 other than the protruding region 15a in the x direction each are preferably equal to or less than 6 mm. In other words, the widths (c) and (g) of the remaining portions of the through hole 15 other than the protruding region 15a in the x direction each are preferably equal to or less than two-thirds of the width (d) of the portion of the through hole 15 in the x direction where the protruding region 15a is formed.

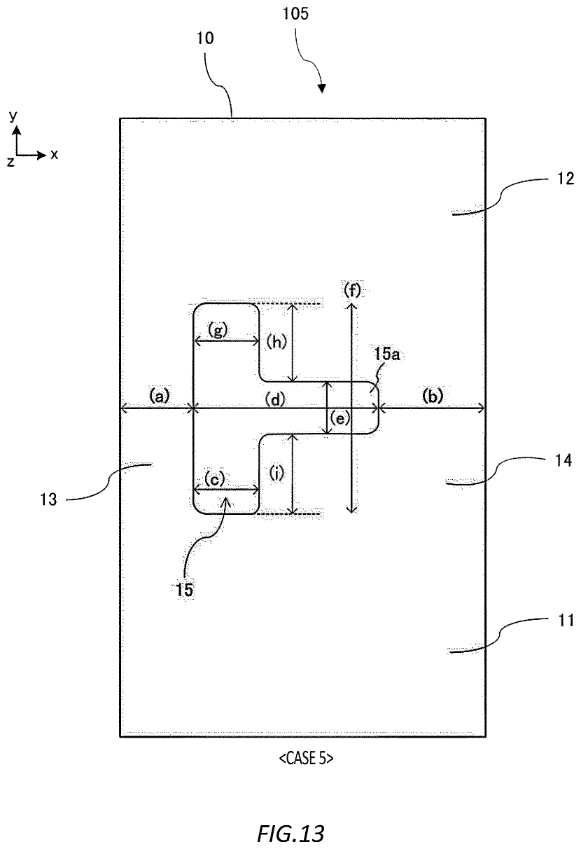

FIG. 13 is a top view illustrating a schematic configuration of a current measurement module 105 of Case 5. In FIG. 13, although the magnetic field sensing unit 20 is arranged within the through hole 15, the illustration thereof is omitted. The current measurement module 105 of Case 5 has a configuration in which the through hole 15 is horizontally mirrored from the current measurement module 104 of Case 4 illustrated in FIG. 10. In FIG. 13, (a)=3.5 mm, (b)=5.5 mm, (c)=3 mm, (d)=9 mm, (e)=2.6 mm, (f)=12.5 mm, (g)=3 mm, (h)=4.95 mm, and (i)=4.95 mm.

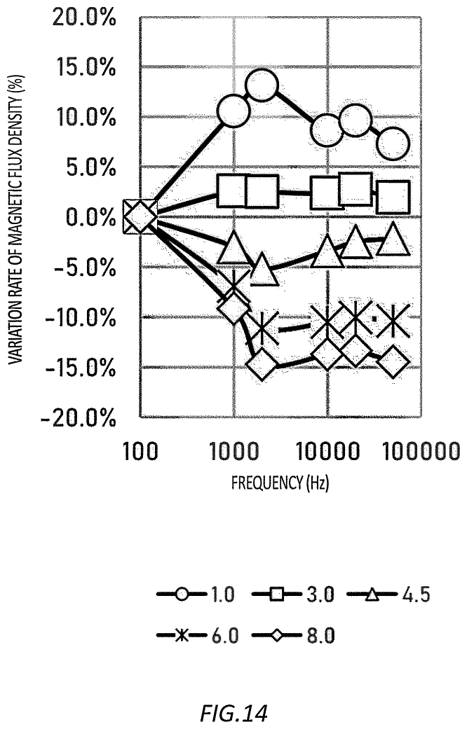

FIG. 14 is a graph illustrating how the positional shift of the magnetic field sensing unit 20 in the x direction influences frequency characteristics for the current measurement module 105 of Case 5. FIG. 14 indicates a variation rate of a magnetic flux density with respect to 100 Hz (%), the magnetic flux density being detected when the two magnetic field sensing elements 21 and 22 of the magnetic field sensing unit 20 move in the x direction within the through hole 15. Other elements in FIG. 14 are the same as those in FIG. 7, so the description thereof is omitted.

As illustrated in FIG. 14, in the current measurement module 105 of Case 5, when the two magnetic field sensing elements 21 and 22 are close to the current path portion 13 (indicated by the open white circles), the variation rate is mostly within a range from +7% to 15%. In addition, when the two magnetic field sensing elements 21 and 22 are close to the current path portion 14 (indicated by the diamonds), the variation rate is mostly in a range from −10% to −15%. Accordingly, when the two magnetic field sensing elements 21 and 22 move in the x direction, there is a difference of approximately 20% to 30% in the variation rate. Accordingly, it is shown that the current measurement module 105 of Case 5 has a low tolerance for the positional shift of the magnetic field sensing unit 20 in the x direction.

From the above comparison of the current measurement module 104 of Case 4 with the current measurement module 105 of Case 5, since the protruding region 15a is formed on one side adjacent to the narrow region 13a (3.5 mm) in Case 4 and the protruding region 15a is formed on an opposite side adjacent to the current path portion 14 (5.5 mm) in Case 5, it is shown that, in the embodiment in which the protruding region 15a is formed on the one side adjacent to the narrow region 13a has a lower tolerance for the positional shift of the magnetic field sensing unit 20 in the x direction. In comparison of the current measurement modules 101 to 104 of Case 1 to Case 4 and the current measurement modules 105 of Case 5 with each other, it is also shown that the protruding region 15a is preferably formed on the one side adjacent to the narrow region 13a, and the width of (a) of the narrow region 13a is preferably the same as the width (b) of the current path portion 14, or narrower than the width (b) of the current path portion 14.

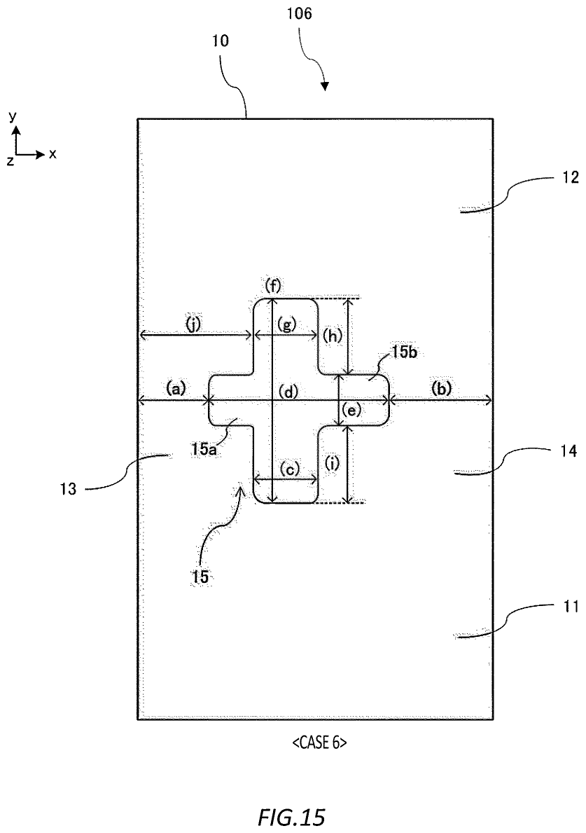

FIG. 15 is a top view illustrating a schematic configuration of a current measurement module 106 of Case 6. In FIG. 15, although the magnetic field sensing unit 20 is arranged within the through hole 15, the illustration thereof is omitted. The current measurement module 106 of Case 6 has a configuration in which the through hole 15 has the protruding region 15a on one side adjacent to the current path portion 13 and a protruding region 15b on another side adjacent to the current path portion 14. The length of the protruding region 15a in the x direction is shorter than a length of the protruding region 15b in the x direction. In FIG. 15, (a)=3.5 mm, (b)=5.5 mm, (c)=3 mm, (d)=9 mm, (e)=2.6 mm, (f)=12.5 mm, (g)=3 mm, (h)=4.95 mm, (i)=4.95 mm, and (j)=5.5 mm.

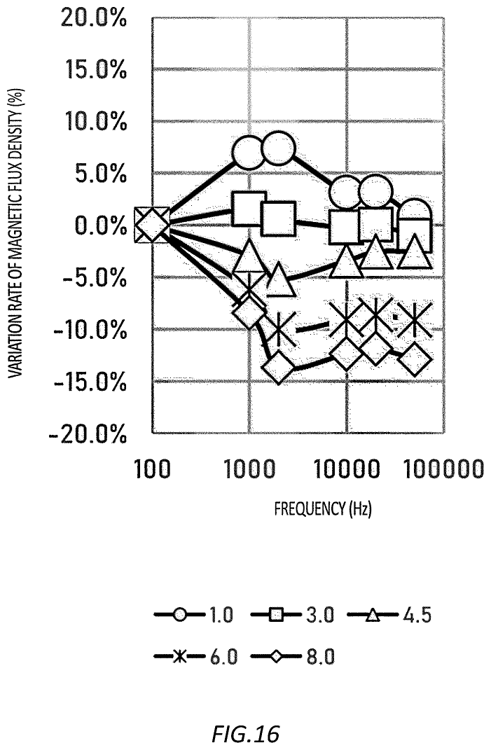

FIG. 16 is a graph illustrating how the positional shift of the magnetic field sensing unit 20 in the x direction influences frequency characteristics for the current measurement module 106 of Case 6. FIG. 16 indicates a variation rate of a magnetic flux density with respect to 100 Hz (%), the magnetic flux density being detected when the two magnetic field sensing elements 21 and 22 of the magnetic field sensing unit 20 move in the x direction within the through hole 15. Other elements in FIG. 16 are the same as those in FIG. 7, so the description thereof is omitted.

As illustrated in FIG. 16, in the current measurement module 106 of Case 6, when the two magnetic field sensing elements 21 and 22 are close to the current path portion 13 (indicated by the open white circles), the variation rate is mostly within a range from +0% to 7%. In addition, when the two magnetic field sensing elements 21 and 22 are close to the current path portion 14 (indicated by the diamonds), the variation rate is mostly in a range from −9% to −15%. Accordingly, when the two magnetic field sensing elements 21 and 22 move in the x direction, there is a difference of approximately 10 to 25% in the variation rate. Accordingly, it is shown that the current measurement module 106 of Case 6 has a low tolerance for the positional shift of the magnetic field sensing unit 20 in the x direction.

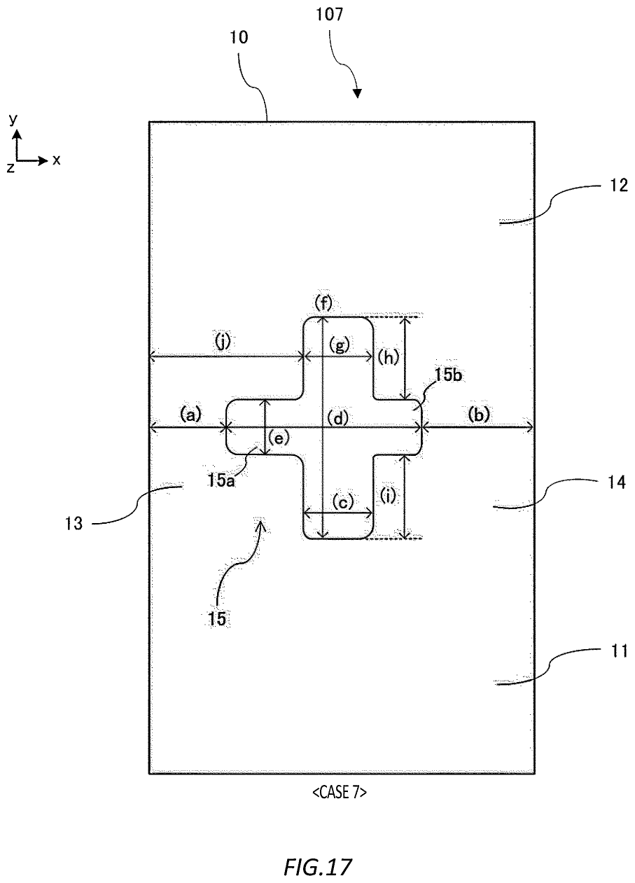

FIG. 17 is a top view illustrating a schematic configuration of a current measurement module 107 of Case 7. In FIG. 17, although the magnetic field sensing unit 20 is arranged within the through hole 15, the illustration thereof is omitted. The current measurement module 107 of Case 7 has a configuration in which the through hole 15 has the protruding region 15a on one side adjacent to the current path portion 13 and the protruding region 15b on another side adjacent to the current path portion 14. The length of the protruding region 15a in the x direction is longer than a length of the protruding region 15b in the x direction. In FIG. 17, (a)=3.5 mm, (b)=5.5 mm, (c)=3 mm, (d)=9 mm, (e)=2.6 mm, (f)=12.5 mm, (g)=3 mm, (h)=4.95 mm, (i)=4.95 mm, and (j)=7.5 mm.

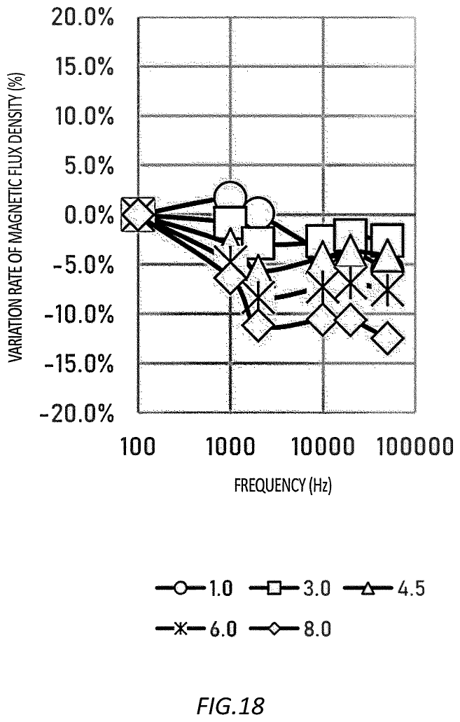

FIG. 18 is a graph illustrating how the positional shift of the magnetic field sensing unit 20 in the x direction influences frequency characteristics for the current measurement module 107 of Case 7. FIG. 18 indicates a variation rate of a magnetic flux density with respect to 100 Hz (%), the magnetic flux density being detected when the two magnetic field sensing elements 21 and 22 of the magnetic field sensing unit 20 move in the x direction within the through hole 15. Other elements in FIG. 18 are the same as those in FIG. 7, so the description thereof is omitted.

As illustrated in FIG. 18, in the current measurement module 107 of Case 7, when the two magnetic field sensing elements 21 and 22 are close to the current path portion 13 (indicated by the open white circles), the variation rate is mostly within a range from +2% to −5%. In addition, when the two magnetic field sensing elements 21 and 22 are close to the current path portion 14 (indicated by the diamonds), the variation rate is mostly in a range from −5% to −13%. Accordingly, when the two magnetic field sensing elements 21 and 22 move in the x direction, there is a difference of approximately 10% in the variation rate. Accordingly, it is shown that the current measurement module 107 of Case 7 has a higher tolerance for the positional shift of the magnetic field sensing unit 20 in the x direction than that of Cases 5 and 6, but has a lower tolerance than that of Cases 2 to 4.

From the above results of the current measurement modules 106 and 107 of Cases 6 and 7, it is shown that the embodiments in which the through hole 15 has the two protruding regions 15a, one on the one side adjacent to the current path portion 13 and one on the another side adjacent to the current path portion 14 each have a lower tolerance for the positional shift of the magnetic field sensing unit 20 in the x direction than that of the embodiments of Cases 2 to 4 in which the through hole 15 has the protruding region 15a only on the one side adjacent to the current path portion 13.

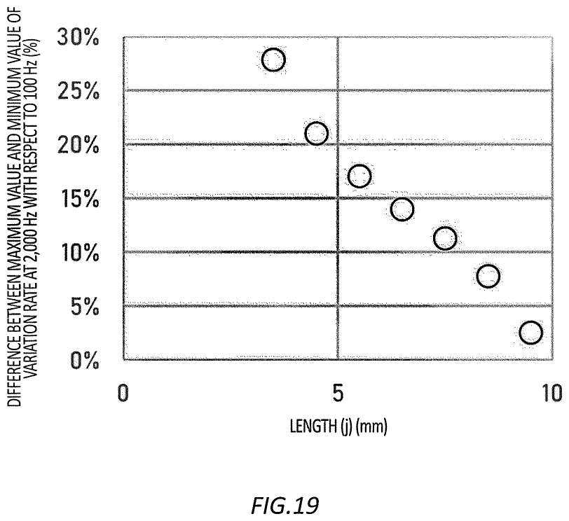

FIG. 19 illustrates how a length of (j) of the current measurement module 106 or 107 (see FIG. 15 or FIG. 17) influences frequency characteristics. The horizontal axis in FIG. 19 represents the length of (j) of the current measurement module 106 or 107 (mm), and the vertical axis in FIG. 19 represents a difference between a maximum value and a minimum value of the variation rate of the magnetic flux density at 2,000 Hz with respect to 100 Hz (%), the magnetic flux density being detected by the two magnetic field sensing elements 21 and 22 of the magnetic field sensing unit 20 when the two magnetic field sensing elements 21 and 22 move by a total of 7 mm in the x direction within the through hole 15.

As illustrated in FIG. 19, a longer length of (j) of the current measurement module 106 or 107 leads to a smaller difference in the variation rate of the magnetic flux density, which can be said to have a preferable influence on the frequency characteristics.

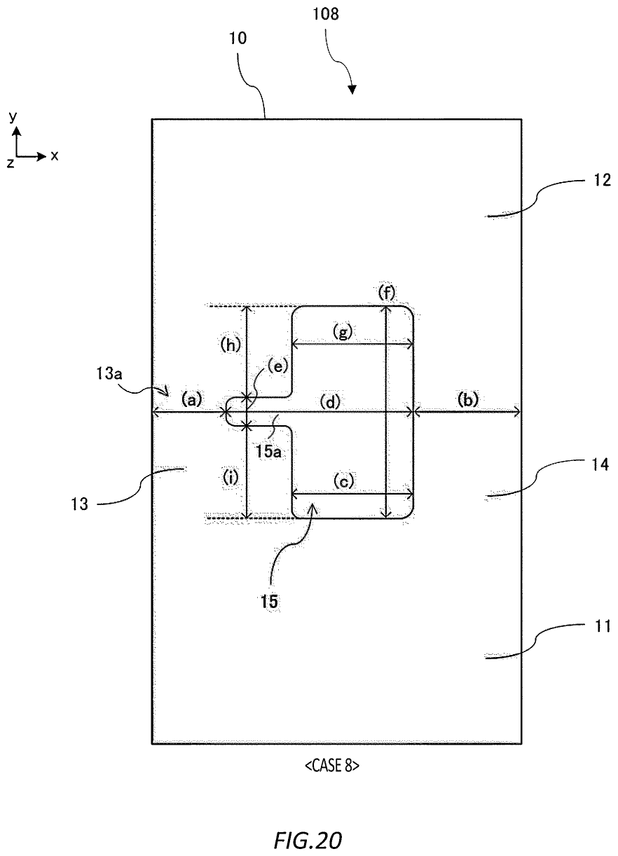

FIG. 20 is a top view illustrating a schematic configuration of a current measurement module 108 of Case 8. In FIG. 20, although the magnetic field sensing unit 20 is arranged within the through hole 15, the illustration thereof is omitted. The current measurement module 108 of Case 8 has a configuration in which the length (e) of the protruding region 15a in the y direction is short. In FIG. 20, (a)=3.5 mm, (b)=5.5 mm, (c)=6 mm, (d)=9 mm, (e)=1.5 mm, (f)=12.5 mm, (g)=6 mm, (h)=4.95 mm, and (i)=4.95 mm.

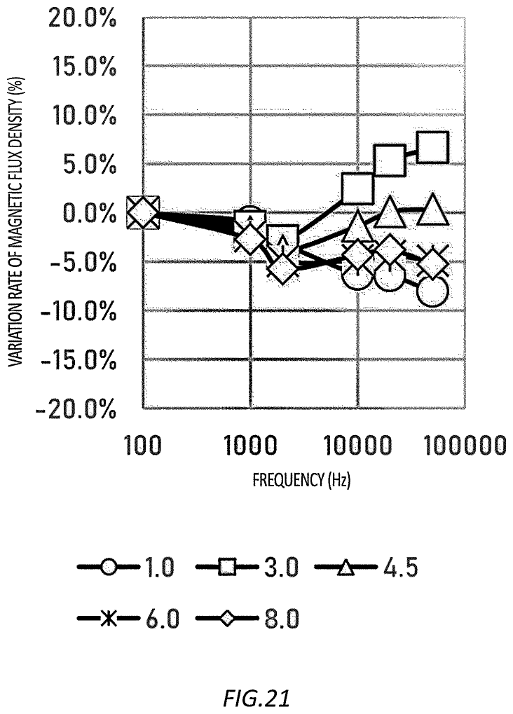

FIG. 21 is a graph illustrating how the positional shift of the magnetic field sensing unit 20 in the x direction influences frequency characteristics for the current measurement module 108 of Case 8. FIG. 21 indicates a variation rate of a magnetic flux density with respect to 100 Hz (%), the magnetic flux density being detected when the two magnetic field sensing elements 21 and 22 of the magnetic field sensing unit 20 move in the x direction within the through hole 15. Other elements in FIG. 21 are the same as those in FIG. 7, so the description thereof is omitted. As illustrated in FIG. 21, in the current measurement module 108 of Case 8, when the two magnetic field sensing elements 21 and 22 are at a distance of 3 mm from the current path portion 13 (indicated by the squares), the variation rate is mostly within a range from +7% to −2%. In addition, when the two magnetic field sensing elements 21 and 22 are at a distance of 1 mm from the current path portion 13 (indicated by the circles), the variation rate is mostly in a range from 0% to −8%. Accordingly, when the two magnetic field sensing elements 21 and 22 move in the x direction, the difference in the variation rate diverges up to roughly 16%. Accordingly, it is shown that the current measurement module 108 of Case 8 has a low tolerance for the positional shift of the magnetic field sensing unit 20 in the x direction.

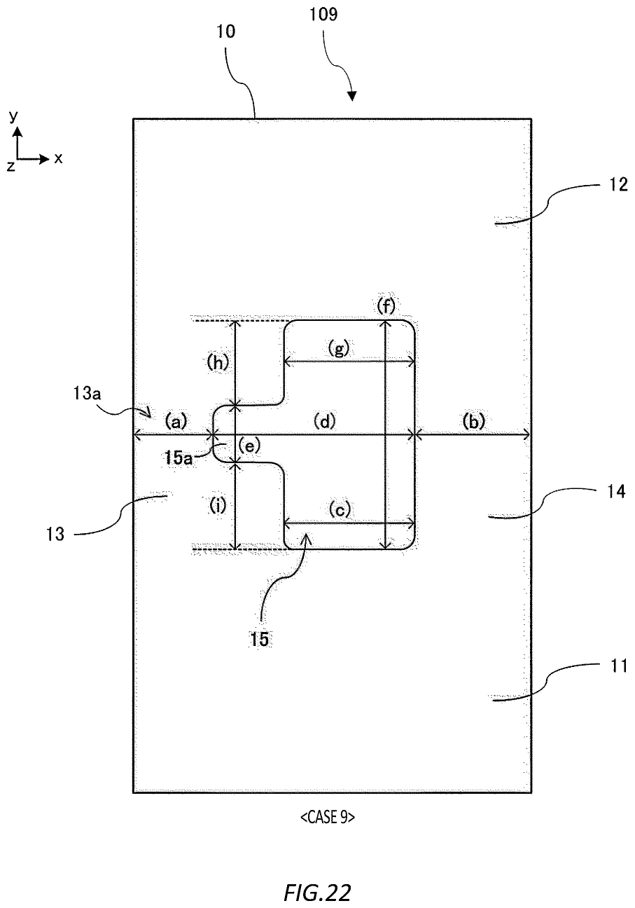

FIG. 22 is a top view illustrating a schematic configuration of a current measurement module 109 of Case 9. In FIG. 22, although the magnetic field sensing unit 20 is arranged within the through hole 15, the illustration thereof is omitted. The current measurement module 109 of Case 9 has a configuration in which the length (e) of the protruding region 15a in the y direction is longer than that in the current measurement module 108 in Case 8. In FIG. 22, (a)=3.5 mm, (b)=5.5 mm, (c)=6 mm, (d)=9 mm, (e)=2.6 mm, (f)=12.5 mm, (g)=6 mm, (h)=4.95 mm, and (i)=4.95 mm.

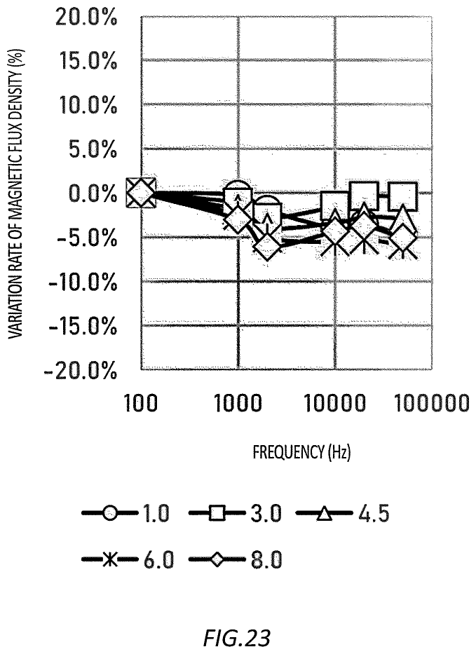

FIG. 23 is a graph illustrating how the positional shift of the magnetic field sensing unit 20 in the x direction influences frequency characteristics for the current measurement module 109 of Case 9. FIG. 23 indicates a variation rate of a magnetic flux density with respect to 100 Hz (%), the magnetic flux density being detected when the two magnetic field sensing elements 21 and 22 of the magnetic field sensing unit 20 move in the x direction within the through hole 15. Other elements in FIG. 23 are the same as those in FIG. 7, so the description thereof is omitted.

As illustrated in FIG. 23, in the current measurement module 109 of Case 9, when the two magnetic field sensing elements 21 and 22 are at a distance of 3 mm from the current path portion 13 (indicated by the squares), the variation rate is mostly within a range from 0% to −2%. In addition, when the two magnetic field sensing elements 21 and 22 are close to the current path portion 14 (indicated by the diamonds), the variation rate is mostly in a range from −4% to −6%. Accordingly, when the two magnetic field sensing elements 21 and 22 move in the x direction, the difference in the variation rate is within a range of 4%. Accordingly, it is shown that the current measurement module 109 of Case 9 has a high tolerance for the positional shift of the magnetic field sensing unit 20 in the x direction.

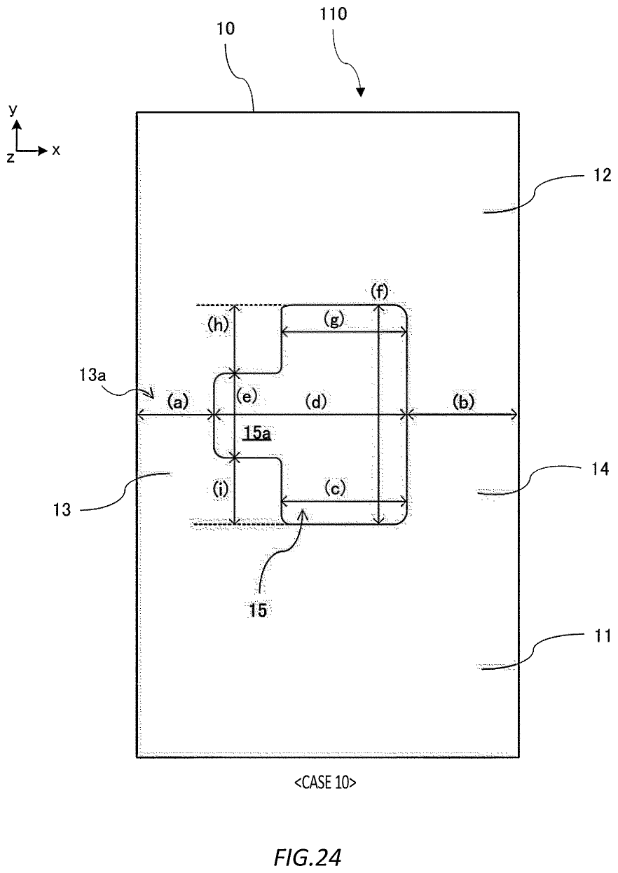

FIG. 24 is a top view illustrating a schematic configuration of a current measurement module 110 of Case 10. In FIG. 24, although the magnetic field sensing unit 20 is arranged within the through hole 15, the illustration thereof is omitted. The current measurement module 110 of Case 10 has a configuration in which the length (e) of the protruding region 15a in the y direction is further longer than that in the current measurement module 109 in Case 9. In FIG. 24, (a)=3.5 mm, (b)=5.5 mm, (c)=6 mm, (d)=9 mm, (e)=6.6 mm, (f)=12.5 mm, (g)=6 mm, (h)=4.95 mm, and (i)=4.95 mm.

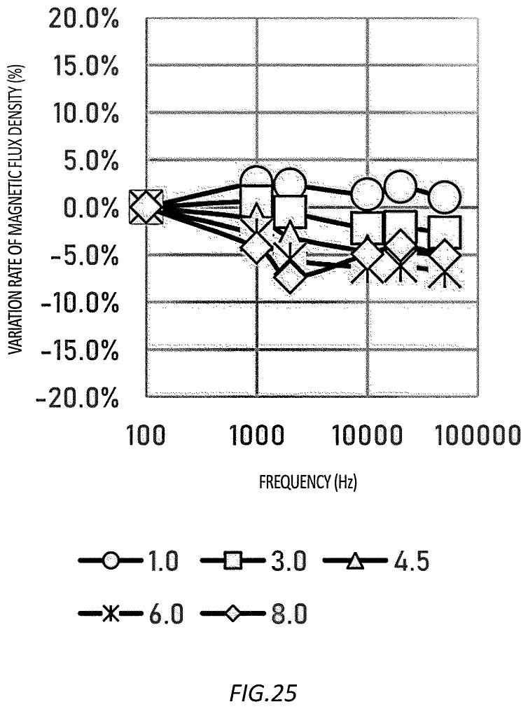

FIG. 25 is a graph illustrating how the positional shift of the magnetic field sensing unit 20 in the x direction influences frequency characteristics for the current measurement module 110 of Case 10. FIG. 25 indicates a variation rate of a magnetic flux density with respect to 100 Hz (%), the magnetic flux density being detected when the two magnetic field sensing elements 21 and 22 of the magnetic field sensing unit 20 move in the x direction within the through hole 15. Other elements in FIG. 25 are the same as those in FIG. 7, so the description thereof is omitted.

As illustrated in FIG. 25, in the current measurement module 110 of Case 10, when the two magnetic field sensing elements 21 and 22 are close to the current path portion 13 (indicated by the circles), the variation rate is mostly within a range from +2% to +3%. In addition, when the two magnetic field sensing elements 21 and 22 are close to the current path portion 14 (indicated by the diamonds), the variation rate is mostly within a range from −5% to −8%. Accordingly, when the two magnetic field sensing elements 21 and 22 move in the x direction, the difference in the variation rate diverges up to 11%. Accordingly, it is shown that the current measurement module 109 of Case 9 has a low tolerance for the positional shift of the magnetic field sensing unit 20 in the x direction.

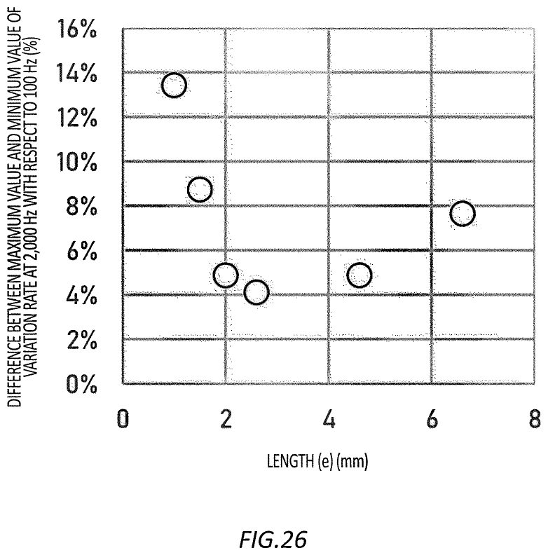

FIG. 26 illustrates how a length of (e) of the current measurement module 100 influences frequency characteristics. The horizontal axis in FIG. 26 represents the length of (e) of the current measurement module 100 (mm), and the vertical axis in FIG. 26 represents a difference between a maximum value and a minimum value of the variation rate of the magnetic flux density at 1,000 Hz with respect to 100 Hz (%), the magnetic flux density being detected by the two magnetic field sensing elements 21 and 22 of the magnetic field sensing unit 20 when the two magnetic field sensing elements 21 and 22 move by a total of 7 mm in the x direction within the through hole 15. In FIG. 26, cases where the length of (e) changes from 1.0 mm to 6.6 mm are illustrated.

As illustrated in FIG. 26, in the cases where the length of (e) of the current measurement module 100 is equal to or less than 1.5 mm and the case where it is 6.6 mm, the difference in the variation rate of the magnetic flux density gets larger, which can be said to have a non-preferable influence on the frequency characteristics. Meanwhile, in the cases where the length of (e) of the current measurement module 100 is within a range from 2 mm to 6 mm, the difference in the variation rate of the magnetic flux density gets smaller, which can be said to have a preferable influence on the frequency characteristics. From the above, the length of (e) of the current measurement module 100 is desirably equal to or more than a thickness of the conductor 10 in the z direction (2 mm) and equal to or less than a half of the length of (f) of the through hole 15 (12.5 mm).

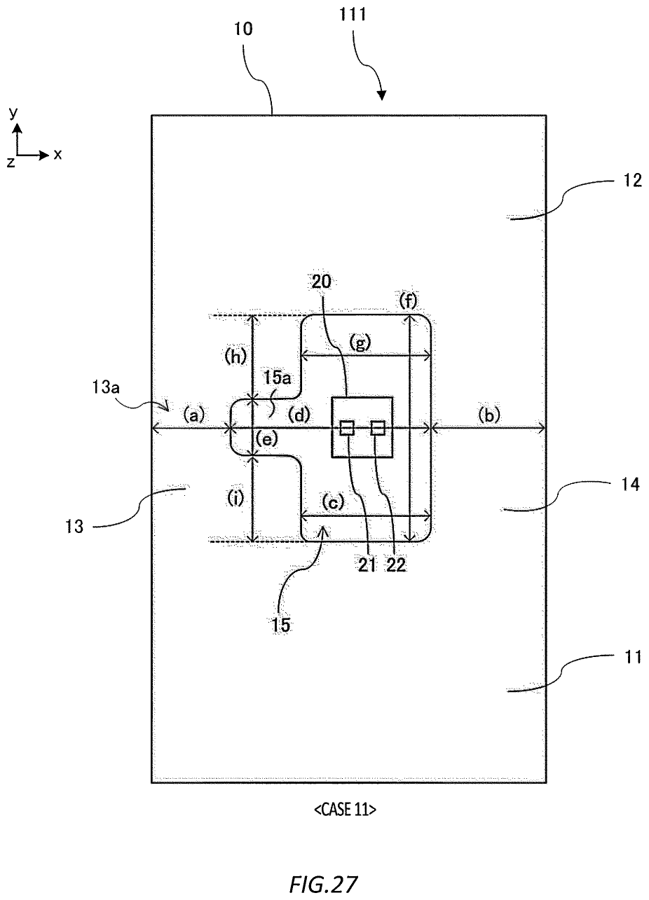

FIG. 27 is a top view illustrating a schematic configuration of a current measurement module 111 of Case 11. In the current measurement module 111 of Case 11, the two magnetic field sensing elements 21 and 22 are arranged side by side in the x direction, and each of the two magnetic field sensing elements 21 and 22 includes a magnetosensitive surface for detecting a component in the z direction orthogonal to the y direction and the x direction of the magnetic fields generated by currents flowing through the two current path portions 13 and 14. Other components are the same as those in the current measurement module 109 of Case 9. In FIG. 27, (a)=3.5 mm, (b)=5.5 mm, (c)=6 mm, (d)=9 mm, (e)=2.6 mm, (f)=12.5 mm, (g)=6 mm, (h)=4.95 mm, and (i)=4.95 mm.

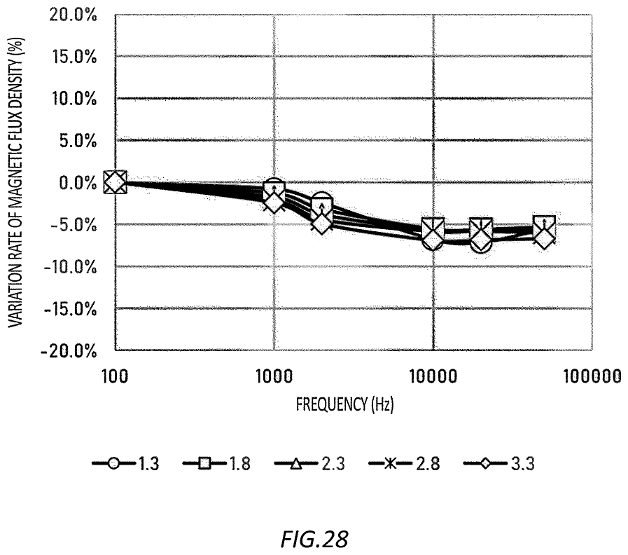

FIG. 28 is a graph illustrating how the positional shift of the magnetic field sensing unit 20 in the x direction influences frequency characteristics for the current measurement module 111 of Case 11. FIG. 28 indicates a variation rate of a magnetic flux density with respect to 100 Hz (%), the magnetic flux density being detected when the two magnetic field sensing elements 21 and 22 of the magnetic field sensing unit 20 move in the x direction within the through hole 15. In FIG. 28, open white circles indicate cases where a distance in the x direction between the left end of the current path portion 13 on the left side and a center position between the two magnetic field sensing elements 21 and 22 is 1.3 mm; squares indicate cases where the distance is 1.8 mm; triangles indicate cases where the distance is 2.3 mm; asterisks indicate cases where the distance is 2.8 mm; and diamonds indicate cases where the distance is 3.3 mm.

As illustrated in FIG. 28, in the current measurement module 111 of Case 11, when the two magnetic field sensing elements 21 and 22 are close to the current path portion 13 (indicated by the circles), the variation rate is mostly within a range from 0% to −7%. In addition, when the two magnetic field sensing elements 21 and 22 are close to the current path portion 14 (indicated by the diamonds), the variation rate is mostly within a range from −3% to −7%. Accordingly, when the two magnetic field sensing elements 21 and 22 move in the x direction, the difference in the variation rate converges into a range of approximately 3%. Accordingly, it is shown that the current measurement module 111 of Case 11 has a high tolerance for the positional shift of the magnetic field sensing unit 20 in the x direction.

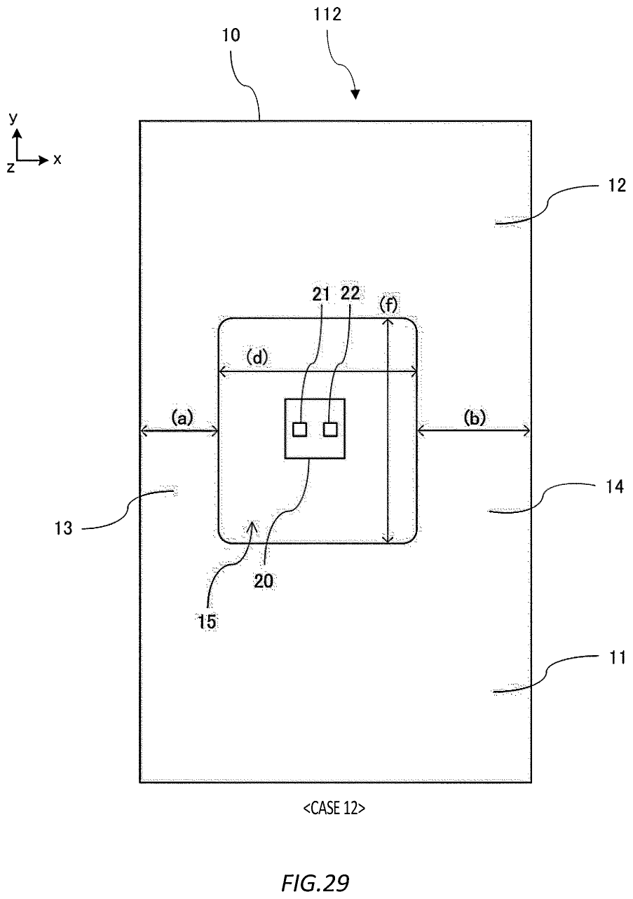

FIG. 29 is a top view illustrating a schematic configuration of a current measurement module 112 of Case 12. In the current measurement module 112 of Case 12, the magnetic field sensing unit 20 is arranged in the x-y plane direction in contrast to the current measurement module 101 of Case 1. That is, the two magnetic field sensing elements 21 and 22 of the magnetic field sensing unit 20 are arranged side by side in the x direction. Other components are the same as those in the current measurement module 101 of Case 1. In FIG. 29, (a)=3.5 mm, (b)=5.5 mm, (d)=9 mm, and (f)=12.5 mm.

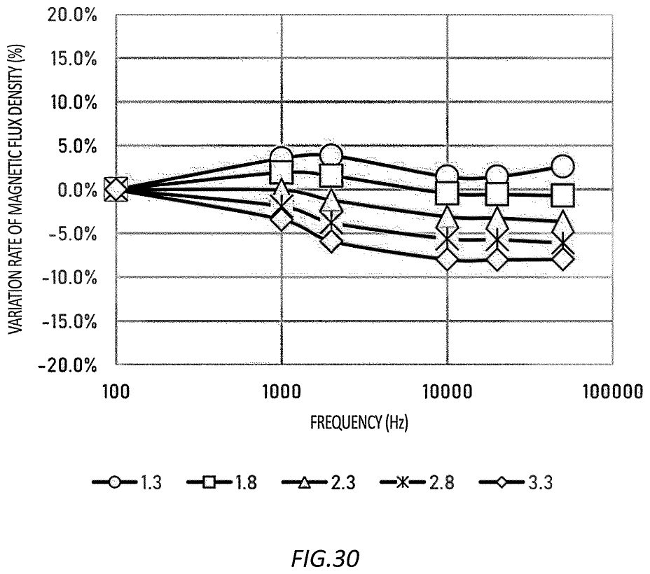

FIG. 30 is a graph illustrating how the positional shift of the magnetic field sensing unit 20 in the x direction influences frequency characteristics for the current measurement module 112 of Case 12. FIG. 30 indicates a variation rate of a magnetic flux density with respect to 100 Hz (%), the magnetic flux density being detected when the two magnetic field sensing elements 21 and 22 of the magnetic field sensing unit 20 move in the x direction within the through hole 15. Other elements in FIG. 30 are the same as those in FIG. 28, so the description thereof is omitted.

As illustrated in FIG. 30, in the current measurement module 112 of Case 12, when the two magnetic field sensing elements 21 and 22 are close to the current path portion 13 (indicated by the circles), the variation rate is mostly within a range from +2% to +5%. In addition, when the two magnetic field sensing elements 21 and 22 are close to the current path portion 14 (indicated by the diamonds), the variation rate is mostly within a range from −4% to −9%. Accordingly, when the two magnetic field sensing elements 21 and 22 move in the x direction, the difference in the variation rate diverges up to 14%. Accordingly, it is shown that the current measurement module 112 of Case 12 has a low tolerance for the positional shift of the magnetic field sensing unit 20 in the x direction.

From the above comparison of the current measurement module 111 of Case 11 with the current measurement module 112 of Case 12, it is shown that the current measurement module 111 of Case 11 has a higher tolerance for the positional shift of the magnetic field sensing unit 20 in the x direction. Accordingly, when the two magnetic field sensing elements 21 and 22 of the magnetic field sensing unit 20 are arranged side by side in the x direction, it is again shown that the embodiment in which the through hole 15 has the protruding region 15a is better.

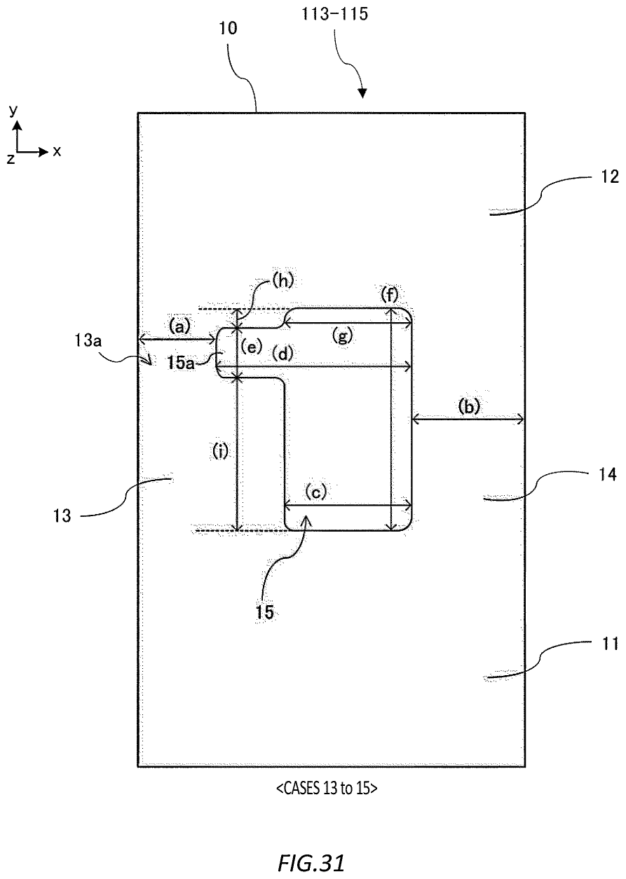

FIG. 31 is a top view illustrating a schematic configuration of current measurement modules 113 to 115 of Cases 13 to 15. In the current measurement modules 113 to 115 of Cases 13 to 15, the protruding region 15a of the through hole 15 moves upward in contrast to the current measurement module 109 of Case 9. That is, (h) changes in a range of 0 to 4.95 mm. Other components are the same as those in the current measurement module 109 of Case 9. In FIG. 31, (a)=3.5 mm, (b)=5.5 mm, (c)=6 mm, (d)=9 mm, (e)=2.6 mm, (f)=12.5 mm, (g)=6 mm, (h)=0 to 4.95 mm, and (i)=4.95 to 9.9 mm. A length of (h) of Case 13 is 0 mm, a length of (h) of Case 14 is 2.4 mm, and a length of (h) of Case 15 is 4.95 mm.

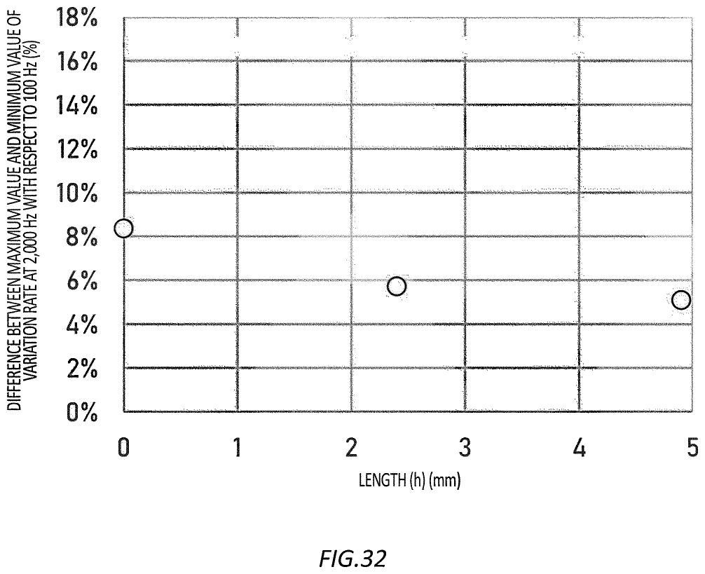

FIG. 32 illustrates how the length of (h) of the current measurement modules 113 to 115 of Cases 13 to 15 influences frequency characteristics. The horizontal axis in FIG. 32 represents the length of (h) of the current measurement module 100 (mm), and the vertical axis in FIG. 32 represents a difference in the variation rate of the magnetic flux density at 2,000 Hz with respect to 100 Hz (%), the magnetic flux density being detected by the two magnetic field sensing elements 21 and 22 of the magnetic field sensing unit 20 when the two magnetic field sensing elements 21 and 22 move by a total of 7 mm in the x direction within the through hole 15. In FIG. 32, a point on the left side indicates a case where the protruding region 15a moves to an upper part of the through hole 15 to yield (h)=0, a middle point indicates a case where (h)=2.4, and a point on the right side indicates a case where the protruding region 15a is in a middle of the through hole 15 to yield (h)=(i).

As illustrated in FIG. 32, a shorter length of (h) of the current measurement module 100 leads to a larger difference in the variation rate of the magnetic flux density, which can be said to have a non-preferable influence on the frequency characteristics. From the above, it is shown that the case where the protruding region 15a is in the middle of the through hole 15 and (h)=(i) is best.

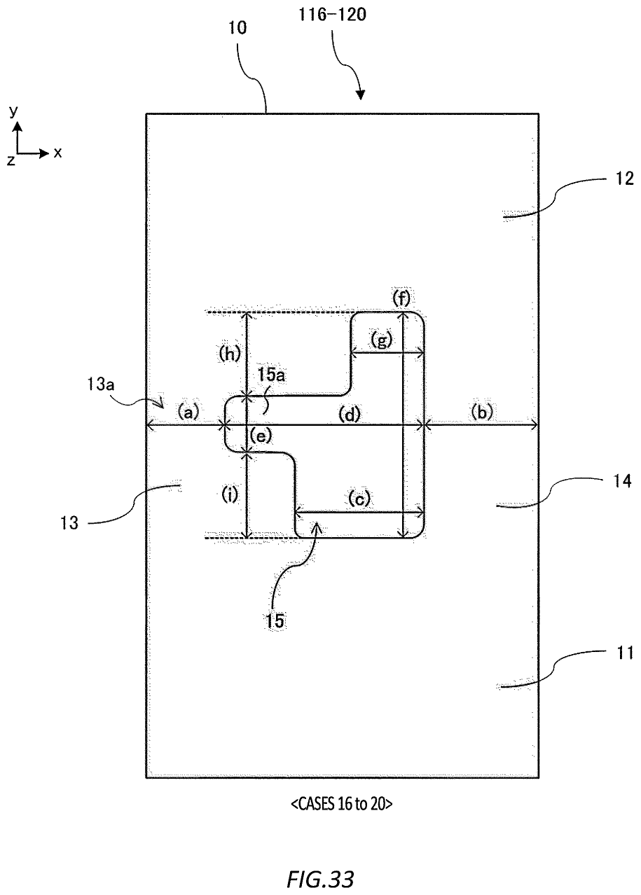

FIG. 33 is a top view illustrating a schematic configuration of current measurement modules 116 to 120 of Cases 16 to 20. In the current measurement modules 116 to 120 of Cases 16 to 20, (g) changes in a range of 3 to 9 mm in contrast to the current measurement module 109 of Case 9. Other components are the same as those in the current measurement module 109 of Case 9. In FIG. 33, (a)=3.5 mm, (b)=5.5 mm, (c)=6 mm, (d)=9 mm, (e)=2.6 mm, (f)=12.5 mm, (g)=3 to 9 mm, (h)=4.95 mm, and (i)=4.95 mm. A length of (g) of Case 16 is 3 mm, a length of (g) of Case 17 is 5 mm, a length of (g) of Case 18 is 6 mm, a length of (g) of Case 19 is 7 mm, and a length of (g) of Case 20 is 9 mm.

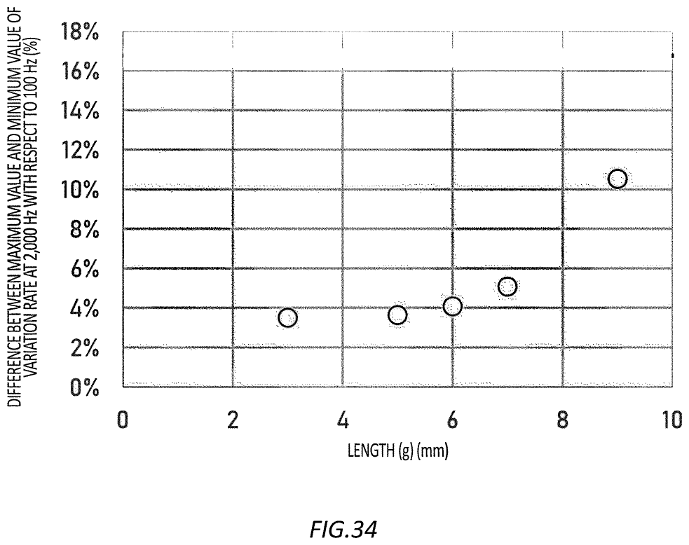

FIG. 34 illustrates how the length of (g) of the current measurement modules 116 to 120 of Cases 16 to 20 influences frequency characteristics. The horizontal axis in FIG. 34 represents the length of (g) of the current measurement module 100 (mm), and the vertical axis in FIG. 34 represents a difference between a maximum value and a minimum value of the variation rate of the magnetic flux density at 2,000 Hz with respect to 100 Hz (%), the magnetic flux density being detected by the two magnetic field sensing elements 21 and 22 of the magnetic field sensing unit 20 when the two magnetic field sensing elements 21 and 22 move by a total of 7 mm in the x direction within the through hole 15. In FIG. 34, numerals in the cases where (g) changes in a range of 3 to 9 mm are indicated. Note that, since (c) does not change while changing (g), the through hole 15 takes a vertically asymmetrical shape.

As illustrated in FIG. 34, a shorter length of (g) of the current measurement module 100 leads to a smaller difference in the variation rate of the magnetic flux density, which can be said to have a preferable influence on the frequency characteristics. Meanwhile, since the difference in the variation rate of the magnetic flux density converges when the length of (g) is equal to or less than 6 mm, it is shown that the length equal to or less than 6 mm for (g) would suffice.

### Effect of the Present Embodiment

In the current measurement module 100 according to the first embodiment, the through hole 15 has the protruding region 15a only on the one side adjacent to the current path portion 13. In this way, the tolerance for the positional shift of the magnetic field sensing unit 20 in the x direction can be improved.

In the current measurement module 100 according to the first embodiment, the widths (c) and (g) of the remaining portions of the through hole 15 other than the protruding region 15a in the x direction each are equal to or less than two-thirds of the width (d) of the portion of the through hole 15 in the x direction where the protruding region 15a is formed. In this way, the tolerance for the positional shift of the magnetic field sensing unit 20 in the x direction can be improved.

In the current measurement module 100 according to the first embodiment, the lengths of the widths (c) and (g) of the remaining portions of the through hole 15 other than the protruding region 15a in the x direction each are equal to or less than 6 mm. In this way, the tolerance for the positional shift of the magnetic field sensing unit 20 in the x direction can be improved.

In the current measurement module 100 according to the first embodiment, the length (e) of the protruding region 15a of the through hole 15 of the current measurement module 100 in the y direction is equal to or less than a half of the length (f) of the through hole 15 in the y direction and equal to or more than a thickness of the conductor 10 in the z direction. In this way, the tolerance for the positional shift of the magnetic field sensing unit 20 in the x direction can be improved.

In the current measurement module 100 according to the first embodiment, the through hole 15 has the protruding region 15a only on the one side adjacent to the current path portion 13, and the two magnetic field sensing elements 21 and 22 of the magnetic field sensing unit 20 are arranged side by side in the z direction (such as in Cases 2 to 4). In this way, the tolerance for the positional shift of the magnetic field sensing unit 20 in the x direction can be improved.

In the current measurement module 100 according to the first embodiment, the through hole 15 has the protruding region 15a only on the one side adjacent to the current path portion 13, and the two magnetic field sensing elements 21 and 22 of the magnetic field sensing unit 20 are arranged side by side in the x direction (Case 11). In this way, the tolerance for the positional shift of the magnetic field sensing unit 20 in the x direction can be improved.

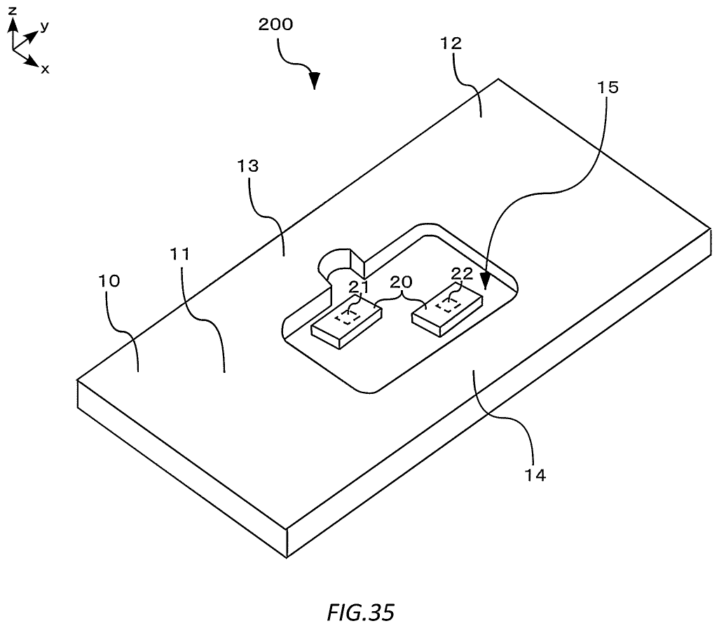

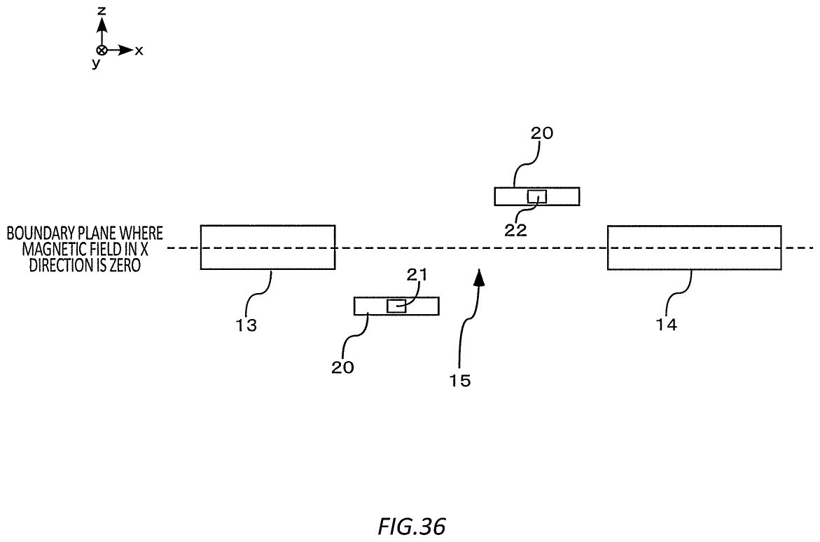

FIG. 35 is a perspective view illustrating an example of a schematic configuration of a current measurement module 200 according to a second embodiment. FIG. 36 is a side sectional view illustrating the example of the schematic configuration of the current measurement module 200 according to the second embodiment. FIG. 36 is a cross-sectional view of the current measurement module 200 according to the second embodiment taken in a plane that goes through the protruding region 15a formed in the through hole 15 and the magnetoelectric conversion elements 21 and 22 and that is parallel to the z-x plane. In the current measurement module 200 according to the second embodiment, a magneto-resistive element is used as each of the two magnetic field sensing elements 21 and 22. The current measurement module 200 according to the second embodiment corresponds to Case 2 of the current measurement module 100 according to the first embodiment. In the current measurement module 200 according to the second embodiment, the two magnetic field sensing elements 21 and 22 of the magnetic field sensing unit 20 are arranged such that a boundary plane where a magnetic field in the x direction generated by a current flowing through the conductor 10 is zero is interposed therebetween in the z direction. In FIG. 36, the boundary plane is illustrated by a dashed line. The two magnetic field sensing elements 21 and 22 may be arranged at different positions in the x direction or may be arranged at a same position in the x direction. Other components of the current measurement module 200 according to the second embodiment are similar to corresponding components in Case 2 of the current measurement module 100 according to the first embodiment, so the corresponding components designate corresponding reference numbers, and the duplicated description thereof is omitted.

As illustrated in FIG. 35 and FIG. 36, when viewed from the z direction, the two magnetic field sensing elements 21 and 22 are arranged at a position where they face the protruding region 15a within the through hole 15. In other words, when viewed from the x direction, the two magnetic field sensing elements 21 and 22 are arranged in a range where the protruding region 15a of the through hole 15 is formed.

In addition, as illustrated in FIG. 35 and FIG. 36, when viewed from each of the x direction and the y direction, the two magnetic field sensing elements 21 and 22 are arranged at different positions in the z direction within the through hole 15. As a more specific example, in the z-x plane, the magnetic field sensing element 21 is located on a negative side in the z direction of a boundary plane where a magnetic field in the x direction of the magnetic fields generated by currents flowing through the two current path portions 13 and 14 is zero, and the magnetic field sensing element 22 is located on a positive side in the z direction of the boundary plane where the magnetic field in the x direction of the magnetic fields generated by currents flowing through the two current path portions 13 and 14 is zero, and they are arranged not to face each other in the x direction nor in the z direction. When the conductor 10 is composed of a uniform material and has a uniform thickness, the magnetic field sensing element 21 is located on the negative side in the z direction of a plane that divides the conductor 10 into two equal parts in the z direction, and the magnetic field sensing element 22 is located on the positive side in the z direction of the plane that divides the conductor 10 into the two equal parts in the z direction. In this case, again, it may be considered that the two magnetic field sensing elements 21 and 22 and the protruding region 15a face each other provided that the protruding region 15a and the magnetic field sensing elements 21 and 22 are at a same position in the y direction, and when viewed from the x direction, it may be considered that the two magnetic field sensing elements 21 and 22 are arranged in the range where the protruding region 15a of the through hole 15 is formed and that they are arranged with the conductor 10 interposed therebetween. Each of the two magnetic field sensing elements 21 and 22 includes a magnetosensitive surface for detecting a component in the x direction of the magnetic fields generated by currents flowing through the two current path portions 13 and 14.

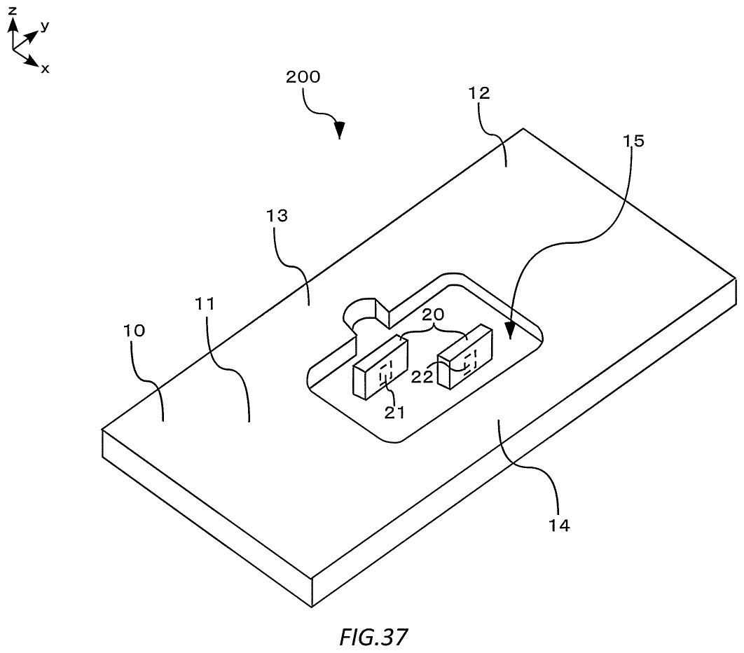

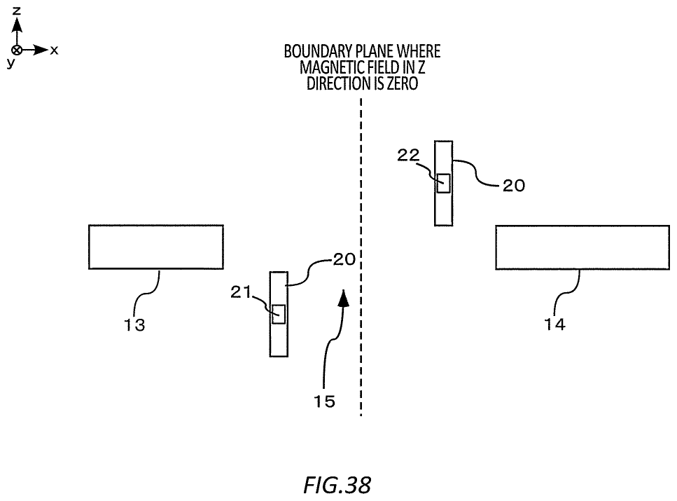

FIG. 37 is a perspective view illustrating another example of the schematic configuration of the current measurement module 200 according to the second embodiment. FIG. 38 is a side sectional view illustrating the another example of the schematic configuration of the current measurement module 200 according to the second embodiment. FIG. 38 is a cross-sectional view of the current measurement module 200 according to the second embodiment taken in a plane that goes through the protruding region 15a formed in the through hole 15 and the magnetoelectric conversion elements 21 and 22 and that is parallel to the z-x plane. Unlike the example illustrated in FIG. 35 to FIG. 36, in the example illustrated in FIG. 37 to FIG. 38, the two magnetic field sensing elements 21 and 22 are arranged such that a boundary plane where a magnetic field in the z direction generated by a current flowing through the conductor 10 is zero is interposed therebetween in the x direction, and each of them includes a magnetosensitive surface for detecting a component in the z direction of the magnetic fields generated by currents flowing through the two current path portions 13 and 14. In FIG. 38, the boundary plane is illustrated by a dashed line. Other components illustrated in FIG. 37 to FIG. 38 are similar to corresponding components illustrated in FIG. 35 to FIG. 36, so the corresponding components designate corresponding reference numbers, and the duplicated description thereof is omitted.

The two magnetic field sensing elements 21 and 22 may be arranged at different positions in the z direction or may be arranged at a same position in the z direction. As illustrated in FIG. 37 to FIG. 38, when viewed from each of the x direction and the y direction, the two magnetic field sensing elements 21 and 22 are arranged at different positions in the z direction within the through hole 15. As a more specific example, in the z-x plane, the magnetic field sensing element 21 is located on a negative side in the x direction of a boundary plane where a magnetic field in the z direction of the magnetic fields generated by currents flowing through the two current path portions 13 and 14 is zero, and the magnetic field sensing element 22 is located on a positive side in the x direction of the boundary plane where the magnetic field in the z direction of the magnetic fields generated by currents flowing through the two current path portions 13 and 14 is zero, and they are arranged not to face each other in the x direction nor in the z direction.

From the above, the current measurement module 200 according to the second embodiment illustrated in FIG. 35 to FIG. 38 has an effect similar to the current measurement module 100 according to the first embodiment. Note that, as an example, the current measurement module 200 according to the second embodiment may use the two magnetic field sensing elements 21 and 22 in a differential manner by arranging the two side by side as a transverse magnetic field sensing element for detecting such as the Tunnel Magneto-resistance (TMR), that is, may cause the elements to sense opposing magnetic fields.

While the present invention has been described by way of the embodiments, the technical scope of the present invention is not limited to the above-described embodiments. It is apparent to persons skilled in the art that various alterations or improvements can be made to the above-described embodiments. It is also apparent from description of the claims that the embodiments to which such modifications or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### EXPLANATION OF REFERENCES

10: conductor;
11, 12: main body portion;
13, 14: current path portion;
13a: narrow region;
15: through hole;
15a: protruding region;
20: magnetic field sensing unit;
21, 22: magnetic field sensing element;
100 to 120, 200: current measurement module.

What is claimed is:

1. A current measurement module comprising:
a conductor including two main body portions arranged side by side in a first direction, and two current path portions arranged side by side in a second direction orthogonal to the first direction with a through hole interposed therebetween and for connecting the two main body portions; and
a magnetic field sensing element including a magnetosensitive surface for detecting magnetic fields generated by currents flowing through the two current path portions, wherein
the through hole has a protruding region which locally protrudes in the second direction only on one side adjacent to a current path portion of the two current path portions, and, in the current path portion on the one side, a narrow region having a same width in the second direction as that of another current path portion of the two current path portions on another side or a narrower width in the second direction than that of the another current path portion of the two current path portions on the another side is formed.

2. The current measurement module according to claim 1, wherein two magnetic field sensing elements are arranged side by side in a third direction orthogonal to the first direction and the second direction, each magnetic field sensing element being identical to the magnetic field sensing element, and each of the two magnetic field sensing elements includes a magnetosensitive surface for detecting a component in the second direction of magnetic fields generated by currents flowing through the two current path portions.

3. The current measurement module according to claim 1, wherein two magnetic field sensing elements are arranged side by side in the second direction, each magnetic field sensing element being identical to the magnetic field sensing element, and each of the two magnetic field sensing elements includes a magnetosensitive surface for detecting a component in a third direction orthogonal to the first direction and the second direction of magnetic fields generated by currents flowing through the two current path portions.

4. The current measurement module according to claim 1, wherein a length of the protruding region in the first direction is equal to or less than a half of a length of the through hole in the first direction and equal to or more than a thickness of the conductor.

5. The current measurement module according to claim 2, wherein a length of the protruding region in the first direction is equal to or less than a half of a length of the through hole in the first direction and equal to or more than a thickness of the conductor.

6. The current measurement module according to claim 3, wherein a length of the protruding region in the first direction is equal to or less than a half of a length of the through hole in the first direction and equal to or more than a thickness of the conductor.

7. The current measurement module according to claim 1, wherein a width of any remaining portion of the through hole other than the protruding region in the second direction is equal to or less than two-thirds of a maximum value of a width of a portion of the through hole in the second direction where the protruding region of the through hole is formed.

8. The current measurement module according to claim 2, wherein a width of any remaining portion of the through hole other than the protruding region in the second direction is equal to or less than two-thirds of a maximum value of a width of a portion of the through hole in the second direction where the protruding region of the through hole is formed.

9. The current measurement module according to claim 3, wherein a width of any remaining portion of the through hole other than the protruding region in the second direction is equal to or less than two-thirds of a maximum value of a width of a portion of the through hole in the second direction where the protruding region of the through hole is formed.

10. The current measurement module according to claim 4, wherein a width of any remaining portion of the through hole other than the protruding region in the second direction is equal to or less than two-thirds of a maximum value of a width of a portion of the through hole in the second direction where the protruding region of the through hole is formed.

11. The current measurement module according to claim 5, wherein a width of any remaining portion of the through hole other than the protruding region in the second direction is equal to or less than two-thirds of a maximum value of a width of a portion of the through hole in the second direction where the protruding region of the through hole is formed.

12. The current measurement module according to claim 6, wherein a width of any remaining portion of the through hole other than the protruding region in the second direction is equal to or less than two-thirds of a maximum value of a width of a portion of the through hole in the second direction where the protruding region of the through hole is formed.

13. The current measurement module according to claim 1, wherein a width of any remaining portion of the through hole other than the protruding region in the second direction is equal to or less than 6 mm.

14. The current measurement module according to claim 2, wherein a width of any remaining portion of the through hole other than the protruding region in the second direction is equal to or less than 6 mm.

15. The current measurement module according to claim 3, wherein a width of any remaining portion of the through hole other than the protruding region in the second direction is equal to or less than 6 mm.

16. The current measurement module according to claim 1, wherein, when viewed from a third direction orthogonal to the first direction and the second direction, the magnetic field sensing element is within the through hole.

17. The current measurement module according to claim 1, wherein, when viewed from the second direction, the magnetic field sensing element is arranged in a range where the protruding region of the through hole is formed.

18. The current measurement module according to claim 1, wherein the magnetic field sensing element is a Hall element.

19. The current measurement module according to claim 1, wherein two magnetic field sensing elements are arranged such that a boundary plane where a magnetic field in the second direction generated by a current flowing through the conductor is zero is interposed therebetween in a third direction orthogonal to the first direction and the second direction, each magnetic field sensing element being identical to the magnetic field sensing element, and each of the two magnetic field sensing elements includes a magnetosensitive surface for detecting a component in the second direction of magnetic fields generated by currents flowing through the two current path portions.

20. The current measurement module according to claim 1, wherein two magnetic field sensing elements are arranged such that a boundary plane where a magnetic field in a third direction orthogonal to the first direction and the second direction generated by a current flowing through the conductor is zero is interposed therebetween in the second direction, each magnetic field sensing element being identical to the magnetic field sensing element, and each of the two magnetic field sensing elements includes a magnetosensitive surface for detecting a component in the third direction of magnetic fields generated by currents flowing through the two current path portions.
